(19) United States
(12) Patent Application Publication
(10) Pub. No.: US 2008/0199808 A1
(43) Pub. Date: Aug. 21, 2008

(54) OPTICAL INFORMATION RECORDING MEDIUM AND METHOD OF RECORDING INFORMATION

(75) Inventors: Keita TAKAHASHI, Kanagawa (JP); Kazutoshi Katayama, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/030,628

(22) Filed: Feb. 13, 2008

(30) Foreign Application Priority Data
Feb. 16, 2007 (JP) 036330/2007

(51) Int. Cl. G03F 7/00

(52) U.S. Cl. 430/270.16; 430/321

(57) ABSTRACT

The optical information recording medium comprises a recording layer comprising a compound denoted by general formula (I).

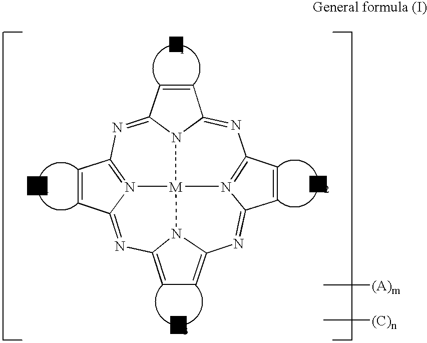

A denotes a hydrogen atom or a substituent, B₁, B₂, B₃, and B₄ each independently denote an atom group forming an aromatic ring with two terminal carbon atoms, M denotes two hydrogen atoms, a divalent to tetravalent metal atom, a metal oxide, a metal atom having a ligand, or a metal oxide having a ligand, C denotes (L-(D)₁) or E, D and E each independently denote a prescribed monovalent substituent, L denotes a divalent linking group, l denotes an integer ranging from 1 to 10, m denotes an integer ranging from 0 to 15, n denotes an integer ranging from 1 to 16, wherein m+n=16.

### CROSS-REFERENCE TO RELATED APPLICATIONS

This application claims the benefit of priority under 35 USC 119 to Japanese Patent Application No. 2007-036330 filed on Feb. 16, 2007, which is expressly incorporated herein by reference in its entirety.

### BACKGROUND OF THE INVENTION

1. Field of the Invention

The present invention relates to an optical information recording medium and a method of recording information permitting the recording and reproducing of information with a laser beam, More particularly, the present invention relates to a heat mode-type optical information recording medium and a method of recording information suited to the recording of information by irradiation of a short-wavelength laser beam.

2. Discussion of the Background

The recordable CD (CD-R) and recordable DVD (DVD-R) have been known as optical information recording media permitting the “write-once” recording of information with a laser beam. In contrast to the recording of information on a CD-R, which is conducted with a laser beam in the infrared range (normally, at a wavelength of about 780 nm), the recording of information on a DVD-R is conducted with a visible light laser beam (with a wavelength of about 630 to 680 nm). Since a recording laser beam of shorter wavelength is employed for a DVD-R than for a CD-R, the DVD-R has an advantage of being able to record at higher density than on a CD-R. Thus, the status of the DVD-R as a high-capacity recording medium has to some degree been ensured in recent years.

Networks, such as the Internet, and high-definition television have recently achieved widespread popularity. With high-definition television (HDTV) broadcasts near at hand, demand is growing for high-capacity recording media for recording image information both economically and conveniently. However, the CD-R and DVD-R do not afford recording capacities that are adequate to handle future needs. Accordingly, to increase the recording density by using a laser beam of even shorter wavelength than that employed in a DVD-R, the development of high-capacity disks capable of recording with laser beams of short wavelength (for example, a wavelength of equal to or less than 440 nm) is progressing. For example, an optical recording disk known as the “Blu-ray,” employing a blue laser of 405 nm, has been proposed.

Japanese Unexamined Patent Publication (KOKAI) No. 2002-301870 or English language family member US 2003/0138728 and WO 2005-000972, which are expressly incorporated herein by reference in their entirety, propose optical information recording media for recording information by irradiation of a short-wavelength laser beam, such as the above-mentioned Blu-ray optical recording disk.

In attaining good recording characteristics in optical information recording, it is desirable to use a dye having absorption at a wavelength close to that of the recording laser beam as the dye in the recording layer. Through investigation, the present inventors found that although the dyes employed in the recording layers of the optical information recording media described in Japanese Unexamined Patent Publication (KOKAI) No. 2002-301870 and WO2005-000972 have absorption in the short wavelength range, they do not necessarily achieve both adequate light-toughness and good recording characteristics.

### SUMMARY OF THE INVENTION

An aspect of the present invention provides for an optical information recording medium having adequate light-toughness and excellent recording characteristics in the recording of information by irradiation of a short-wavelength laser beam, and to provide a method of recording information permitting good recording by irradiation of a short-wavelength laser beam.

In optical information recording, irradiation of a laser beam onto an optical information recording medium causes the irradiated portion of the recording layer to absorb the laser beam, locally raising the temperature. This produces a physical or chemical change (such as generating pits), thereby altering the optical characteristics and recording information. Reading (reproduction) of information is conducted by irradiation of a laser beam of the same wavelength as the laser beam employed in recording, for example, onto the optical information recording medium, and detecting the difference in the refractive index between portions where the optical characteristics of the recording layer have been changed (recorded portions) and portions where they have not (unrecorded portions). Thus, the greater the difference in refractive index between recorded portions and unrecorded portions, the greater the reading precision. As a result of investigation, the present inventors have found that in the optical information recording media described in Japanese Unexamined Patent Publication (KOKAI) No. 2002-301870 and WO2005-000972, adequate recording characteristics are not achieved because an adequate difference in refractive index before and after recording is not achieved.

The present inventors conducted extensive research on the basis of the above, resulting in the discovery that compounds containing prescribed substituents afforded good light-toughness, and that using such compounds as recording layer dyes made it possible to achieve a large difference in refractive index by forming voids in pits by thermally decomposing the substituents contained in these compounds during recording. The present invention was devised upon this basis.

An aspect of the present invention relates to an optical information recording medium comprising a recording layer comprising a dye on a support, wherein said dye is a compound denoted by general formula (I).

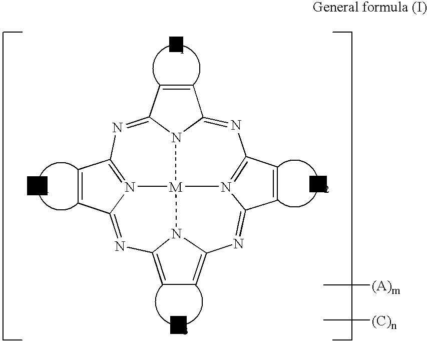

[In general formula (I), A denotes a hydrogen atom or a substituent, B₁, B₂, B₃, and B₄ each independently denote an atom group forming an aromatic ring with two terminal carbon atoms, M denotes two hydrogen atoms, a divalent to tetravalent metal atom, a metal oxide, a metal atom having a ligand, or a metal oxide having a ligand, C denotes (L-(D)₁) or E, D and E each independently denote a monovalent substituent denoted by general formula (II) or (XIII), L denotes a divalent linking group, l denotes an integer ranging from 1 to 10, m denotes an integer ranging from 0 to 15, n denotes an integer ranging from 1 to 16, wherein m+n=16, plural As may be identical or different from each other when m is an integer of equal to or greater than 2, and plural (L-(D)₁)s or Es may be identical or different from each other when n is an integer of equal to or greater than 2.]

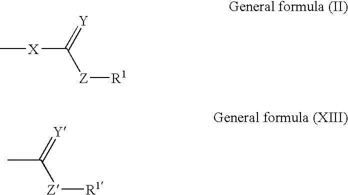

[In general formulas (II) and (XIII), R¹ and R^{1′each} each independently denote a secondary alkyl group, X denotes a sulfur atom, an oxygen atom, NR², or CR³R⁴, Y and Y′ each independently denote an oxygen atom or a sulfur atom, Z and Z′ each independently denote NR², an oxygen atom, or a sulfur atom, and R², R³, and R⁴ each independently denote a hydrogen atom or a monovalent substituent.]

Both of Y and Z in general formula (II) may be an oxygen atom and/or both of Y′ and Z′ in general formula (XIII) may be an oxygen atom.

The above compound denoted by general formula (I) may have a thermal decomposition temperature ranging from 300 to 400° C.

The optical information recording medium may comprise said recording layer, a barrier layer, an adhesive layer, and a cover layer in this order on the support.

A further aspect of the present invention relates to a method of recording information on the recording layer comprised in the above optical information recording medium by irradiation of a laser beam onto the optical information recording medium.

The above laser beam may have a wavelength ranging from 390 to 440 nm.

The present invention can provide an optical information recording medium having excellent light-toughness and excellent recording characteristics in the short wavelength region.

Other exemplary embodiments and advantages of the present invention may be ascertained by reviewing the present disclosure and the accompanying drawings.

### BRIEF DESCRIPTION OF THE DRAWINGS

The present invention will be described in the following text by the exemplary, non-limiting embodiments shown in the figures, wherein:

FIG. 1 is a schematic sectional view of an example of the optical information recording medium of the present invention.

FIG. 2 is a schematic sectional view of an example of the optical information recording medium of the present invention.

Explanations of symbols in the drawings are as follows:

10A First optical information recording medium

10B Second optical information recording medium

12 First support

14 First recordable recording layer

16 Cover layer

18 First light reflective layer

20 Barrier layer

22 First intermediate layer

24 Second support

26 Second recordable recording layer

28 Protective support

30 Second light reflective layer

32 Second bonding layer

44 Hard coat layer

### DESCRIPTIONS OF THE EMBODIMENTS

The following preferred specific embodiments are, therefore, to be construed as merely illustrative, and non-limiting to the remainder of the disclosure in any way whatsoever. In this regard, no attempt is made to show structural details of the present invention in more detail than is necessary for fundamental understanding of the present invention; the description taken with the drawings making apparent to those skilled in the art how several forms of the present invention may be embodied in practice.

### Optical Information Recording Medium

The optical information recording medium of the present invention comprises a recording layer comprising a dye in the form of a compound denoted by general formula (I) on a support.

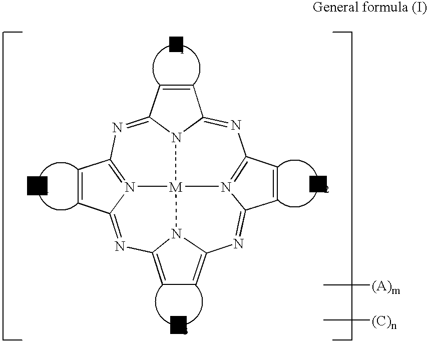

In the optical information recording medium of the present invention, excellent recording characteristics can be achieved by incorporating the compound denoted by general formula (I) as a recording layer dye. Further, a recording layer comprising the compound denoted by general formula (I) also has excellent light-toughness. The present inventors surmise that the reasons for which a recording layer containing the compound exhibits excellent recording characteristics and light-toughness are as follows:

When the laser beam is irradiated onto a recording layer comprising the above compound, the dye residue denoted by general formula (III) below absorbs the laser beam, heating up. This heat thermally decomposes the monovalent substituent denoted by general formula (II) or (XIII) below, producing a gas. This gas is then thought to form voids within pits. In a recording layer comprising the compound denoted by general formula (I), the refractive index of portions that have not been irradiated by the laser beam is generally about 1.6 to 1.9, while that of portions in which voids have been formed by irradiation of the laser beam is about 1.0, varying greatly with the refractive index of unirradiated portions. Thus, a large difference in refractive index can be achieved, which is thought to permit enhanced recording characteristics.

Further, as a result of investigation conducted by the present inventors, it has been found that light-toughness can be greatly enhanced by bonding together a dye residue denoted by general formula (III) and a substituent denoted by general formula (II) or (XIII).

The optical information recording medium of the present invention can achieve both high light-toughness and good recording characteristics in the short-wavelength range by incorporating a compound denoted by general formula (I) having the above-stated characteristics into the recording layer.

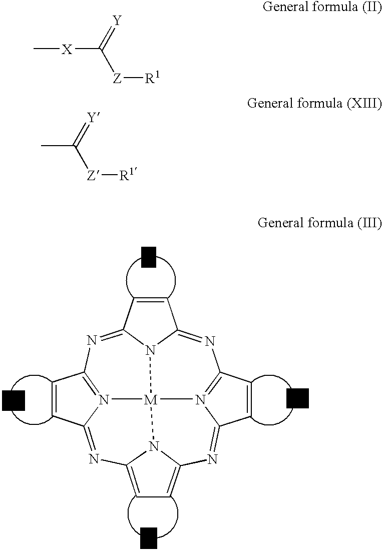

The compound denoted by general formula (I) will be described below.

In general formula (I), A denotes a hydrogen atom or a substituent.

Examples of substituents denoted by A are: halogen atoms, alkyl groups (including cycloalkyl groups), alkenyl groups (including cycloalkenyl groups), alkynyl groups, aryl groups, heterocyclic groups, cyano groups, hydroxyl groups, nitro groups, carboxyl groups, alkoxy groups, aryloxy groups, silyloxy groups, heterocyclic oxy groups, acyloxy groups, carbamoyloxy groups, alkoxycarbonyloxy groups, aryloxycarbonyloxy groups, amino groups (including anilino groups), acylamino groups, aminocarbonylamino groups, alkoxycarbonylamino groups, aryloxycarbonylamino groups, sulfamoylamino groups, alkyl and arylsulfonylamino groups, mercapto groups, alkylthio groups, arylthio groups, heterocyclic thio groups, sulfamoyl groups, sulfo groups, alkyl and arylsulfinyl groups, alkyl and arylsulfonyl groups, acyl groups, aryloxycarbonyl groups, alkoxycarbonyl groups, carbamoyl groups, aryl and heterocyclic azo groups, imido groups, phosphino groups, phophinyl groups, phosphinyloxy groups, phosphinylamino groups, and silyl groups.

Details of the substituent denoted by A will be described in detail below.

Specific examples of halogen atoms are chlorine, bromine, and iodine atoms.

The alkyl groups include linear, branched chain, and cyclic substituted and unsubstituted alkyl groups, specific examples of which are: alkyl groups (preferably alkyl groups having 1 to 30 carbon atoms, such as methyl groups, ethyl groups, n-propyl groups, isopropyl groups, t-butyl groups, n-octyl groups, eicosyl groups, 2-chloroethyl groups, 2-cyanoethyl groups, and 2-ethylhexyl groups) and cycloalkyl groups (preferably substituted or unsubstituted cycloalkyl groups having 3 to 30 carbon atoms, such as cyclohexyl groups, cyclopentyl groups, and 4-n-dodecylcyclohexyl groups). The cycloalkyl groups include bicycloalkyl groups (preferably substituted or unsubstituted bicycloalkyl groups having 5 to 30 carbon atoms, that is, monovalent groups in which a single hydrogen atom has been removed from a bicycloalkane having 5 to 30 carbon atoms, such as bicyclo[1,2,2]-heptane-2-yl and bicyclo[2,2,2]octane-3-yl), and tricyclo structures comprising a greater number of rings. The term alkyl group as used hereinafter (for example, the alkyl group in an alkylthio group) will denote an alkyl group consistent with this concept.

The alkenyl groups include linear, branched chain, and cyclic substituted and unsubstituted alkenyl groups. Examples are: alkenyl groups (preferably substituted or unsubstituted alkenyl groups having 2 to 30 carbon atoms, such as vinyl groups, allyl groups, prenyl groups, geranyl groups, and oleyl groups); cycloalkenyl groups (preferably substituted or unsubstituted cycloalkenyl groups having 3 to 30 carbon atoms, that is, monovalent groups in which a single hydrogen atom has been removed from a cycloalkene having 3 to 30 carbon atoms, such as 2-cyclopentene-1-yl and 2-cyclohexene-1-yl). The cycloalkenyl groups include bicycloalkenyl groups (substituted or unsubstituted bicycloalkenyl groups, preferably substituted or unsubstituted bicycloalkenyl groups having 5 to 30 carbon atoms, that is, monovalent groups in which a single hydrogen atom has been removed from a bicycloalkene having a single double bond, such as bicyclo[2,2,1]hepto-2-ene-1-yl and bicyclo[2,2,2]octo-2-ene-4-yl).

The alkynyl groups are preferably substituted or unsubstituted alkynyl groups having 2 to 30 carbon atoms, such as ethynyl groups, propargyl groups, or trimethylsilylethynyl groups.

The aryl groups are preferably substituted or unsubstituted aryl groups having 6 to 30 carbon atoms, such as phenyl groups, p-tolyl groups, naphthyl groups, m-chlorophenyl groups, or o-hexadecanoylaminophenyl groups.

The heterocyclic groups are preferably monovalent groups in the form of five or six-membered substituted or unsubstituted aromatic or nonaromatic heterocyclic compounds from which a hydrogen atom has been removed, more preferably five or six-membered aromatic heterocyclic groups having 3 to 30 carbon atoms. Specific examples are: 2-furyl groups, 2-thienyl groups, 2-pyrimidinyl groups, and 2-benzothiazolyl groups.

The alkoxy groups are preferably substituted or unsubstituted alkoxy groups having 1 to 30 carbon atoms, such as methoxy groups, ethoxy groups, isopropoxy groups, t-butoxy groups, n-octyloxy groups, and 2-methoxyethoxy groups.

The aryloxy groups are preferably substituted or unsubstituted aryloxy groups having 6 to 30 carbon atoms, such as phenoxy groups, 2-methylphenoxy groups, 4-t-butylphenoxy groups, 3-nitrophenoxy groups, and 2-tetradecanoylaminophenoxy groups.

The silyloxy groups are preferably silyloxy groups having 3 to 20 carbon atoms, such as trimethylsilyloxy groups and t-butyldimethylsilyloxy groups.

The heterocyclic oxy groups are preferably substituted or unsubstituted heterocyclic oxy groups having 2 to 30 carbon atoms, 1-phenyltetrazole-5-oxy groups, or 2-tetrahydropyranyloxy groups.

The acyloxy groups are preferably formyloxy groups, substituted or unsubstituted alkylcarbonyloxy groups having 2 to 30 carbon atoms, or substituted or unsubstituted arylcarbonyloxy groups having 6 to 30 carbon atoms, such as formyloxy groups, acetyloxy groups, pivaloyloxy groups, stearoyloxy groups, benzoyloxy groups, or p-methoxyphenylcarbonyloxy groups.

The carbamoyloxy groups are preferably substituted or unsubstituted carbamoyloxy groups having 1 to 30 carbon atoms, such as N,N-dimethylcarbamoyloxy groups, N,N-diethylcarbamoyloxy groups, morpholinocarbonyloxy groups, N,N-di-n-octylamainocarbonyloxy groups, or N-n-octylcarbamoyloxy groups.

The alkoxycarbonyloxy groups are preferably substituted or unsubstituted alkoxycarbonyloxy groups having 2 to 30 carbon atoms, such as methoxycarbonyloxy groups, ethoxycarbonyloxy groups, t-butoxycarbonyloxy groups, or n-octylcarbonyloxy groups.

The aryloxycarbonyloxy groups are preferably substituted or unsubstituted aryloxycarbonyloxy groups having 7 to 30 carbon atoms, such as phenoxycarbonyloxy groups, p-methoxyphenoxycarbonyloxy groups, or p-n-hexadecyloxyphenoxycarbonyloxy groups.

The amino groups are preferably amino groups, substituted or unsubstituted alkylamino groups having 1 to 30 carbon atoms, or substituted or unsubstituted anilino groups having 6 to 30 carbon atoms, such as methylamino groups, dimethylamino groups, anilino groups, N-methylanilino groups, or diphenylamino groups.

The acylamino groups are preferably formylamino groups, substituted or unsubstituted alkylcarbonylamino groups having 1 to 30 carbon atoms, or substituted or unsubstituted arylcarbonylamino groups having 6 to 30 carbon atoms, such as formylamino groups, acetylamino groups, pivaloylamino groups, lauroylamino groups, benzoylamino groups, or 3,4,5-tri-n-octyloxyphenylcarbonylamino groups.

The aminocarbonylamino groups are preferably substituted or unsubstituted aminocarbonylamino groups having 1 to 30 carbon atoms, such as carbamoylamino groups, N,N-dimethylaminocarbonylamino groups, N,N-diethylaminocarbonylamino groups, or morpholinocarbonylamino groups.

The alkoxycarbonylamino groups are preferably substituted or unsubstituted alkoxycarbonylamino groups having 2 to 30 carbon atoms, such as methoxycarbonylamino groups, ethoxycarbonylamino groups, t-butoxycarbonylamino groups, n-octadecyloxycarbonylamino groups, or N-methylmethoxycarbonylamino groups.

The aryloxycarbonylamino groups are preferably substituted or unsubstituted aryloxycarbonylamino groups having 7 to 30 carbon atoms, such as phenoxycarbonylamino groups, p-chlorophenoxycarbonylamino groups, or m-(n-octyloxy)phenoxycarbonylamino.

The sulfamoylamino groups are preferably substituted or unsubstituted sulfamoylamino groups having 0 to 30 carbon atoms, such as sulfamoylamino groups, N,N-dimethylaminosulfonylamino groups, or N-n-octylaminosulfonylamino groups.

The alkyl and arylsulfonylamino groups are preferably substituted or unsubstituted alkylsulfonylamino groups having 1 to 30 carbon atoms or substituted or unsubstituted arylsulfonylamino groups having 6 to 30 carbon atoms, such as methylsulfonylamino groups, butylsulfonylamino groups, phenylsulfonylamino groups, 2,3,5-trichlorophenylsulfonylamino groups, or p-methylphenylsulfonylamino groups.

The alkylthio groups are preferably substituted or unsubstituted alkylthio groups having 1 to 30 carbon atoms, such as methylthio groups, ethylthio groups, or n-hexadecylthio groups.

The arylthio groups are preferably substituted or unsubstituted arylthio groups having 6 to 30 carbon atoms, such as phenylthio groups, p-chlorophenylthio groups, or m-methoxyphenylthio groups.

The heterocyclic thio groups are preferably substituted or unsubstituted heterocyclic thio groups having 2 to 30 carbon atoms, such as 2-benzothiazolylthio groups or 1-phenyltetrazole-5-ylthio groups.

The sulfamoyl groups are preferably substituted or unsubstituted sulfamoyl groups having 0 to 30 carbon atoms, such as N-ethylsulfamoyl groups, N-(3-dodecyloxypropyl)sulfamoyl groups, N,N-dimethylsulfamoyl groups, N-acetylsulfamoyl groups, N-benzoylsulfamoyl groups, or N-(N′-phenylcarbamoyl)sulfamoyl groups.

The alkyl and arylsulfinyl groups are preferably substituted or unsubstituted alkylsulfinyl groups having 1 to 30 carbon atoms or substituted or unsubstituted arylsulfinyl groups having 6 to 30 carbon atoms, such as methylsulfinyl groups, cthylsulfinyl groups, phenylsulfinyl groups, or p-methylphenylsulfinyl groups.

The alkyl and arylsulfonyl groups are preferably substituted or unsubstituted alkylsulfonyl groups having 1 to 30 carbon atoms or substituted or unsubstituted arylsulfonyl groups having 6 to 30 carbon atoms, such as methylsulfonyl groups, ethylsulfonyl groups, phenylsulfonyl groups, or p-methylphenylsulfonyl groups.

The acyl groups are preferably formyl groups, substituted or unsubstituted alkylcarbonyl groups having 2 to 30 carbon atoms, substituted or unsubstituted arylcarbonyl groups having 7 to 30 carbon atoms, or substituted or unsubstituted heterocyclic carbonyl groups having 4 to 30 carbon atoms in which the carbonyl groups are bonded through carbon atoms, such as acetyl groups, pivaloyl groups, 2-chloroacetyl groups, stearoyl groups, benzoyl groups, p-n-octyloxyphenylcarbonyl groups, 2-pyridylcarbonyl groups, or 2-furylcarbonyl groups.

The aryloxycarbonyl groups are preferably substituted or unsubstituted aryloxycarbonyl groups having 7 to 30 carbon atoms, such as phenoxycarbonyl groups, o-chlorophenoxycarbonyl groups, m-nitrophenoxycarbonyl groups, or p-t-butylphenoxycarbonyl groups.

The alkoxycarbonyl groups are preferably substituted or unsubstituted alkoxycarbonyl groups having 2 to 30 carbon atoms, such as methoxycarbonyl groups, ethoxycarbonyl groups, t-butoxycarbonyl groups, or n-octadecyloxycarbonyl groups.

The carbamoyl groups are preferably substituted or unsubstituted carbamoyl groups having 1 to 30 carbon atoms, such as carbamoyl groups, N-methylcarbamoyl groups, N,N-dimethylcarbamoyl groups, N,N-di-n-octylcarbamoyl groups, or N-(methylsulfonyl)carbamoyl groups.

The aryl and heterocyclic azo groups are preferably substituted or unsubstituted arylazo groups having 6 to 30 carbon atoms or substituted or unsubstituted heterocyclic azo groups having 3 to 30 carbon atoms, such as phenylazo groups, p-chlorophenylazo groups, or 5-ethylthio-1,3,4-thiadiazole-2-ylazo groups.

The imido groups are preferably N-succinimide groups or N-phthalimide groups.

The phosphino groups are preferably substituted or unsubstituted phosphino groups having 2 to 30 carbon atoms, such as dimethylphosphino groups, diphenylphosphino groups, or methylphenoxyphosphino groups.

The phosphinyl groups are preferably substituted or unsubstituted phosphinyl groups having 2 to 30 carbon atoms, such as phosphinyl groups, dioctyloxyphosphinyl groups, or diethoxyphosphinyl groups.

The phosphinyloxy groups are preferably substituted or unsubstituted phosphinyloxy groups having 2 to 30 carbon atoms, such as diphenoxyphosphinyl groups or dioctyloxyphosphinyloxy groups.

The phosphinylamino groups are preferably substituted or unsubstituted phosphinylamino groups having 2 to 30 carbon atoms, such as dimethoxyphosphinylamino groups or dimethylaminophosphinylamino groups.

The silyl groups preferably denote substituted or unsubstituted silyl groups having 3 to 30 carbon atoms, such as trimethylsilyl groups, t-butyldimethylsilyl groups, or phenyldimethylsilyl groups.

In those of the above functional groups that comprise a hydrogen atom, the hydrogen atom may be replaced with any one of the above-listed substituents. Examples of such functional groups are alkylcarbonylaminosulfonyl groups, arylcarbonylaminosulfonyl groups, alkylsulfonylaminocarbonyl groups, and arylsulfonylaminocarbonyl groups. Specific examples are methylsulfonylaminocarbonyl groups, p-methylphenylsulfonylaminocarbonyl groups, acetylaminosulfonyl groups, and benzoylaminosulfonyl groups.

In general formula (I), B₁, B₂, B₃, and B₄ each independently denote an atom group forming an aromatic ring with two terminal carbon atoms. The following aromatic rings are examples of the aromatic ring that is formed.

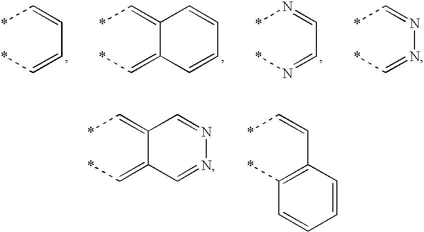

Of these, the following aromatic rings are preferable.

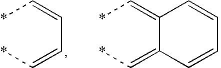

Of these, the following aromatic ring is more preferable.

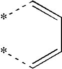

In the above, “*” denotes the positions of bonding with the two terminal carbon atoms.

M denotes two hydrogen atoms, a divalent to tetravalent metal atom, a metal oxide, a metal atom having a ligand, or a metal oxide having a ligand.

The metal atoms are preferably selected from the group consisting of copper, nickel, iron, cobalt, palladium, magnesium, aluminum, zinc, vanadium and silicon.

The metal oxides are preferably oxides containing at least one of the above metal atoms.

Examples of the ligands are: halogen atoms, aryl groups having 6 to 30 carbon atoms, five-membered and six-membered heterocyclic groups, cyano groups, and hydroxyl groups.

Of these, M preferably denotes copper, zinc, magnesium, vanadium, nickel or palladium, more preferably copper, zinc, or magnesium.

In general formula (I), C denotes (L-(D)₁) or E, preferably (L-(D)₁).

L denotes a divalent linking group. Examples of divalent linking groups are: alkylene groups (including cycloalkylene groups), alkenylene groups (including cycloalkenylene groups), alkynylene groups, arylene groups, heterocyclic linking groups (including heteroarylene groups), a carbonyl linking group (—C═O—), a thiocarbonyl linking group (—C═S—), an oxygen atom linking group (—O—), nitrogen atom linking groups (—NA¹-, where A¹ is defined identically with A in general formula (I)), a sulfur atom linking group (—S—), a silylene group (—SiA²A³-, where A² and A³ are each defined identically with A in general formula (I), and may together form a ring), and combinations of these linking groups. In the present invention, cycloalkylene groups include bicycloalkynylene groups, tricyclo structures comprising a greater number of rings, and the like; and the cycloalkenylene groups include bicycloalkenylene groups, tricyclo structures comprising a greater number of rings, and the like.

More specifically, L may denote a divalent group in the form of one of the monovalent substituents described above for A, from which a hydrogen atom has been removed. L preferably denotes a divalent group in which a hydrogen atom has been removed from a monovalent substituent that promotes association (is highly planar), such as an aryl group, heterocyclic group, aryloxy group, heterocyclic oxy group, arylthio group, or heterocyclic thio group, with a divalent group obtained by removing a hydrogen atom from a heterocyclic group, aryloxy group, heterocyclic oxy group, arylthio group, or heterocyclic thio group of greater preference.

In general formula (I), D and E each independently denote a monovalent substituent denoted by general formula (II) or (XIII) below.

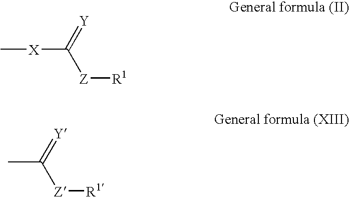

General formulas (II) and (XIII) will be described below.

In general Formulas (II) and (XIII), R¹ and R^{1′} each independently denote a secondary alkyl group. The alkyl groups include linear, branched chain, and cyclicic substituted and unsubstituted alkyl groups, specific examples of which are: alkyl groups (preferably alkyl groups having 3 to 30 carbon atoms, such as isopropyl groups, 2-butyl groups, 2-pentyl groups, 3-pentyl groups, and 2-hexyl groups) and cycloalkyl groups (preferably substituted or unsubstituted cycloalkyl groups having 3 to 30 carbon atoms, such as cyclohexyl groups, cyclopentyl groups, and menthyl groups). The cycloalkyl groups include bicycloalkyl groups (preferably substituted or unsubstituted bicycloalkyl groups having 5 to 30 carbon atoms in the form of monovalent groups in which a hydrogen atom has been removed from a bicycloalkane having 5 to 30 carbon atoms, examples of which are bicyclo[1,2,2]heptane-2-yl and bicyclo[2,2,2]octane-3-yl), and tricyclo structures comprising a greater number of rings. R¹ preferably denotes a cycloalkyl group or an alkyl group having 3 to 30 carbon atoms, more preferably a branched alkyl group having 3 to 20 carbon atoms.

In general formula (II), X denotes a sulfur atom, an oxygen atom, NR², or CR³R⁴. R², R³, or R⁴ each independently denote a hydrogen atom or a monovalent substituent. The substituent may be a substituted or unsubstituted alkyl group (preferably having 1 to 20 carbon atoms, such as a methyl group, ethyl group, n-propyl group, isopropyl group, n-butyl group, n-pentyl group, benzyl group, 3-sulfopropyl group, 4-sulfobutyl group, 3-methyl-3-sulfopropyl group, 2′-sulfobenzyl group, carboxymethyl group, or 5-carboxypentyl group); a substituted or unsubstituted alkenyl group (preferably having 2 to 20 carbon atoms, such as a vinyl group or allyl group); a substituted or unsubstituted aryl group (preferably having 6 to 20 carbon atoms, such as a phenyl group, 2-chlorophenyl group, 4-methoxyphenyl group, 3-methylphenyl group, or 1-naphthyl group); or a substituted or unsubstituted heterocyclic group (preferably having 1 to 20 carbon atoms, such as a pyridyl group, thienyl group, furyl group, thiazolyl group, imidazolyl group, pyrazolyl group, pyrrolidino group, piperidino group, or morpholino group). R², R³, and R⁴ preferably denote hydrogen atoms, substituted or unsubstituted alkyl groups, substituted or unsubstituted phenyl groups, or substituted or unsubstituted heterocyclic groups; more preferably denoting hydrogen atoms, substituted or unsubstituted alkyl groups, or substituted or unsubstituted phenyl groups. In general formula (II), X preferably denotes NR².

In general formulas (II) and (XIII), Y and Y′ each independently denote an oxygen atom or a sulfur atom. Z and Z′ each independently denote NR², an oxygen atom, or a sulfur atom. In general formula (II), both Y and Z preferably denote oxygen atoms. In general formula (XIII), both Y′ and Z′ preferably denote oxygen atoms.

In a preferable embodiment of the substituent denoted by general formula (II), both Y and Z in general formula (II) denote oxygen atoms; this embodiment is the monovalent substituent denoted by general formula (IV) below.

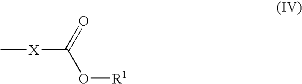

In general formula (IV), both R¹ and X are defined as in general formula (II).

The substituent denoted by general formula (11) is further preferably substituent (a) or (b) below, in which the X in general formula (IV) denotes NR or an oxygen atom. In the substituent denoted by general formula (XIII), Y′ and Z′ in general formula (XIII) preferably denote oxygen atoms, as shown in substituent (c) below.

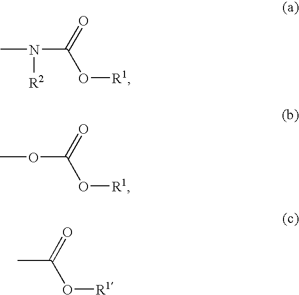

In general formula (I), m denotes an integer ranging from 0 to 15 and n denotes an integer ranging from 1 to 16, with m+n=16. When m denotes an integer of equal to or greater than 2, plural As may be identical or different from each other. When n denotes an integer of equal to or greater than 2, plural (L-(D)₁)s or Es may be identical or different from each other. m preferably denotes an integer falling within a range of 0 to 12, more preferably 0 to 4. n preferably denotes an integer falling within a range of 1 to 8, more preferably 1 to 4. l denotes an integer ranging from 1 to 10. 1 preferably denotes an integer falling within a range of 1 to 4, more preferably 1 to 2.

The substituents denoted by general formulas (II) and (XIII) are capable of generating gas through thermal decomposition. The gas that is generated will vary with the substituent. With respect to the thermal decomposition behavior of the secondary ester groups, it is known that isopropyl ester group decomposes as follows to produce a propylene gas (N. A. Al-Awadi, R. F. Al-Bashir, O. M. E. ElDusouqui, Tetrahedron Lett., 1989, 30, 1699-1702., which is expressly incorporated herein by reference in its entirety).

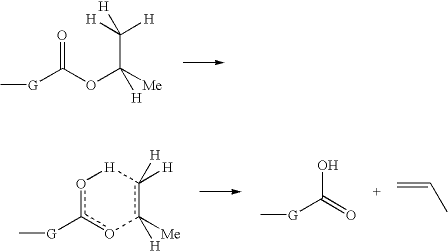

[In the above, G denotes a substituent.]

In the compound denoted by general formula (I), it is preferable that the dye residue denoted by general formula (III) absorbs a laser beam that is irradiated to record information, and the resulting heat causes the substituent denoted by general formula (II) or (XIII) to generate a gas. Thereby, voids can be formed in pits.

In the compound denoted by general formula (I), incorporation of the substituent denoted by general formula (II) or (XIII) can enhance solubility, affording good suitability to manufacturing.

The fact that light-toughness is enhanced by incorporating a linking group that promotes association into the dye residue denoted by general formula (III) is widely known (see L. Howe, J. Z. Zhang, J. Phys. Chem. A, 1997, 101, 3207-3213 (referred to as “Reference A” hereinafter), which is expressly incorporated herein by reference in its entirety). Reference A describes that for an identical water-soluble phthalocyanine dye in water of high association strength and in an organic solvent of low association strength, the lifetime of the excited state in water is from 1/7 to 1/10 that of the lifetime in the organic solvent. That is, it is thought that the greater the association strength, the more effectively the excitation energy is mitigated, and the less singlet oxygen causing deterioration of light-toughness is produced. However, solubility is thought to deteriorate when highly planar linking groups that promote association are incorporated. By contrast, as a result of research, the present inventors discovered that, even when C denoted (L-(D)₁)) having a linking group L in the compound denoted by general formula (I), the introduction of a specific substituent D permitted the simultaneous achievement of solubility, light-toughness, and recording performance.

To enhance sensitivity, it is further preferable to employ a compound with a good thermal decomposition property as the above compound. The thermal decomposition temperature can be employed as an indicator of the thermal decomposition property. In the present invention, the use of a compound with a thermal decomposition temperature of, for example, 300 to 400° C. is preferable, with 320 to 400° C. being more preferable and 330 to 380° C. being of even greater preference. In the present invention, the thermal decomposition temperature refers to a value that is obtained by TG/DTA measurement. As a specific example, an EXSTAR 6000 made by Seiko Instruments, Inc. may be employed to raise the temperature at a rate of 10° C./min over a range of 30 to 550° C. under an N₂ gas flow (at a flow rate of 200 mL/min), and the temperature at the point in time where the rate of weight reduction reaches 10 percent adopted as the thermal decomposition temperature.

The compound denoted by general formula (I) is preferably denoted by general formula (VII) or (VIII) below.

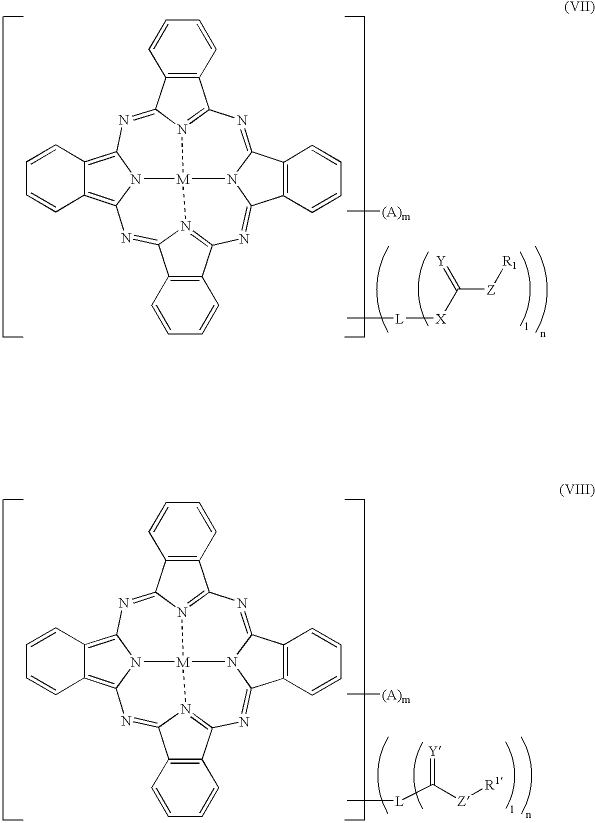

The compound denoted by general formula (I) is more preferably denoted by general formula (IX) or (X) below.

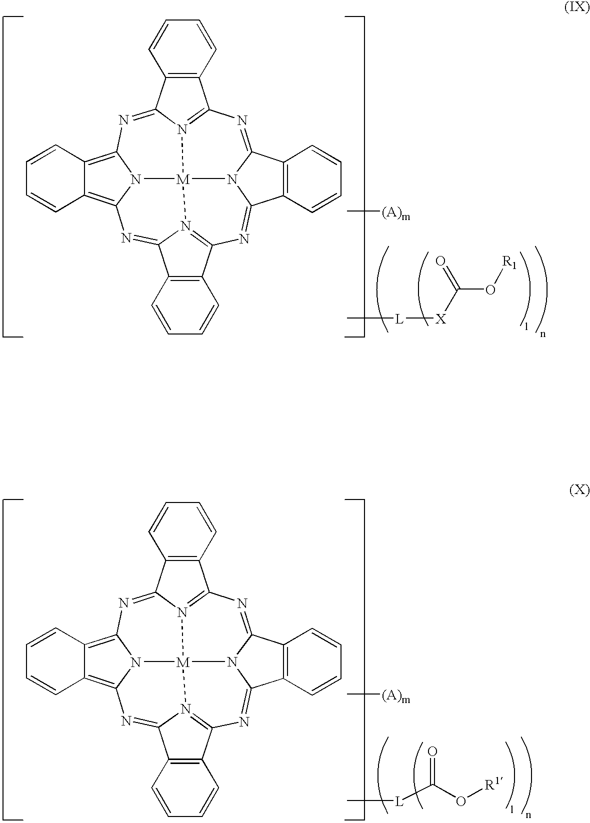

The compound denoted by general formula (IX) above is further preferably denoted by general formula (XI) or (XII) below.

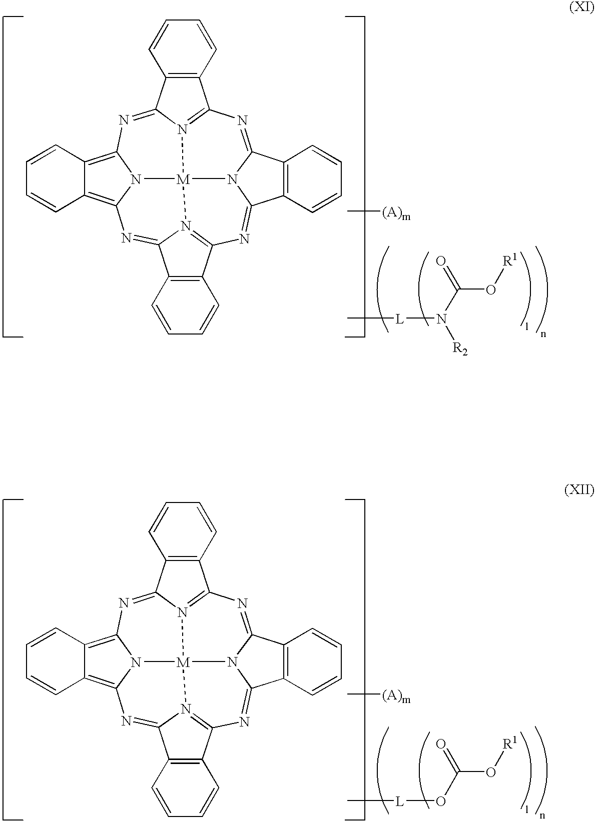

Details of R¹, R^{1′}, R², X, Y, Z, Y′, Z′, L, A, M, n, m, and l in general formulas (VII) to (XII) are identical to those given in the description of general formula (I) above.

In general formula (I), when the dye residue denoted by general formula (III) is a phthalocyanine dye residue, the moiety denoted by —(C)n is preferably substituted at the beta-position on the phthalocyanine ring. The “beta-position on the phthalocyanine ring” means a substitution position on the side further away from the pyrrole ring in the benzopyrrole ring that is normally a constituent component of a phthalocyanine ring. Specifically, these are the positions at which R^{β1} to R^{β8} are substituted in the general structure of phthalocyanine indicated below. In the general structure given below, it is possible for R^{α1} to R^{α8} and R^{β1} to R^{β8} adjacent to each other to form a ring, but it is preferable that R^{α1} to R^{α8} and R^{β1} to R^{β8} not all form rings.

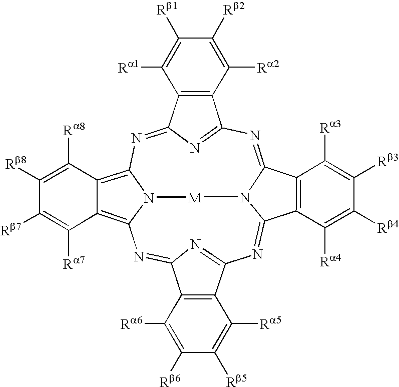

[In the above, R^{α1} to R^{α8} and R^{β1} to R^{β8} each independently denote a hydrogen atom or a substituent, and preferable examples thereof are given in Table 1 below.

The compound denoted by general formula (I) may be bonded at any position to form a polymer. In such cases, the individual units may be identical or different from each other, and may be bonded to polymer chains such as polystyrene, polymethacrylate, polyvinylalcohol, or cellulose.

The compound denoted by general formula (I) may be employed singly in the form of a prescribed derivative, or multiple derivatives of differing structure may be mixed for use. In particular, to prevent crystallization of the recording layer, it is preferable to employ a mixture of isomers in which the substituents are substituted at different positions.

Specific preferable examples of compounds denoted by general formula (I) are given below. However, the present invention is not limited to these examples.

In Table 1 below, for example, the notation “R^{α1}/R^{α2}” means either R^{α1} or R^{α2}. Accordingly, the compound thus denoted is a mixture of substitution-position isomers. In the case of no substitution—that is, when hydrogen atoms are substituted—the notation is omitted.

TABLE 1

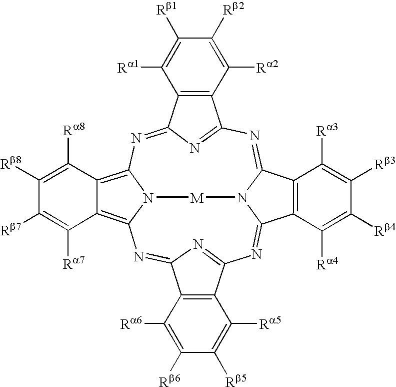

| No. | Position and type of substituent | M |
|---|---|---|
| (I-1) | R^{β1}/R^{β2}, R^{β3}/R^{β4}, R^{β5}/R^{β6}, R^{β7}/R^{β8} | Cu |
| | —COOCH(CH₃)₂ | |
| (I-2) | R^{α1}/R^{α2}, R^{α3}/R^{α4}, R^{α5}/R^{α6}, R^{α7}/R^{α8} | Cu |
| | —COOCH(CH₃)₂ | |
| (I-3) | R^{β1}/R^{β2}, R^{β3}/R^{β4}, R^{β5}/R^{β6}, R^{β7}/R^{β8} | Cu |
| | —COOCH(CH₃)C₂H₅ | |
| (I-4) | R^{α1}/R^{α2}, R^{α3}/R^{α4}, R^{α5}/R^{α6}, R^{α7}/R^{α8} | Zn |
| | —COOCH(CH₃)₂ | |
| (I-5) | R^{α1}/R^{α2}, R^{α3}/R^{α4}, R^{α5}/R^{α6}, R^{α7}/R^{α8} | Cu |
| | 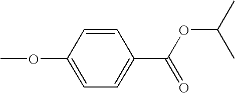 | |
| (I-6) | R^{β1}/R^{β2}, R^{β3}/R^{β4}, R^{β5}/R^{β6}, R^{β7}/R^{β8} | Cu |
| | 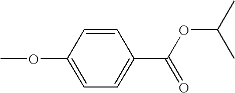 | |
| (I-7) | R^{β1}/R^{β2}, R^{β3}/R^{β4}, R^{β5}/R^{β6}, R^{β7}/R^{β8} | Mg |
| | 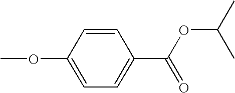 | |
| (I-8) | R^{β1}/R^{β2}, R^{β3}/R^{β4}, R^{β5}/R^{β6}, R^{β7}/R^{β8} | Zn |
| | 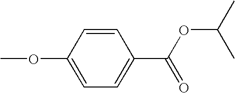 | |
| (I-9) | R^{β1}/R^{β2}, R^{β3}/R^{β4}, R^{β5}/R^{β6}, R^{β7}/R^{β8} | Cu |
| | 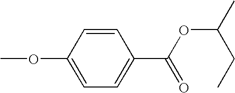 | |
| (I-10) | R^{α1}/R^{α2}, R^{α3}/R^{α4}, R^{α5}/R^{α6}, R^{α7}/R^{α8} | Cu |
| | 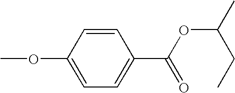 | |
| (I-11) | R^{β1}/R^{β2}, R^{β3}/R^{β4}, R^{β5}/R^{β6}, R^{β7}/R^{β8} | Cu |
| | 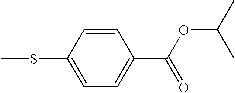 | |
| (I-12) | R^{β1}/R^{β2}, R^{β3}/R^{β4}, R^{β5}/R^{β6}, R^{β7}/R^{β8} | Zn |
| | 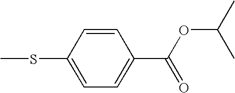 | |
| (I-13) | R^{α1}/R^{α2}, R^{α3}/R^{α4}, R^{α5}/R^{α6}, R^{α7}/R^{α8} | Cu |
| | 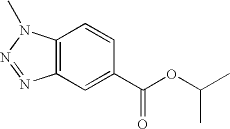 | |
| (I-14) | R^{β1}/R^{β2}, R^{β3}/R^{β4}, R^{β5}/R^{β6}, R^{β7}/R^{β8} | Cu |
| | 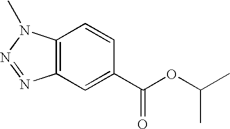 | |
| (I-15) | R^{α1}/R^{α2}, R^{α3}/R^{α4}, R^{β5}/R^{β6}, R^{β7}/R^{β8} | Cu |
| | 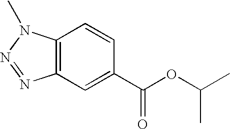 | |
| (I-16) | R^{α1}/R^{α2}, R^{α3}/R^{α4}, R^{β5}/R^{β6}, R^{β7}/R^{β8} | Mg |
| | 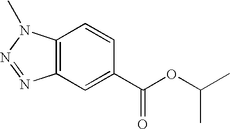 | |
| (I-17) | R^{α1}/R^{α2}, R^{α3}/R^{α4}, R^{β5}/R^{β6}, R^{β7}/R^{β8} | Zn |
| | 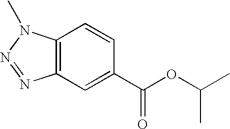 | |

The compound denoted by general formula (I) that has been described above can be synthesized by known methods (for example, by using the method described by Shirai and Kobayashi, pub. by IPC, Inc., “Phthalocyanines—Chemistry and Functions” (pp. 1-62); that described by C. C. Leznoff and A. B. P. Lever, pub. by VCH, “Phthalocyanines—Properties and Applications” (pp. 1-54), which are expressly incorporated herein by reference in their entirety; or method cited therein or a similar method). Some of them can also be obtained in the form of a commercial product.

A single dye denoted by general formula (I), or a combination of two or more such dyes, may be used as the dye in the recording layer. It is also possible to combine dyes other than those denoted by general formula (I) for use. Dyes that can be thus combined are: azo dyes, azo metal dyes, oxonol dyes, cyanine dyes, merocyanine dyes, and the like. The dyes of preference in this regard are azo dyes, azo metal dyes, and oxonol dyes, with azo metal dyes and oxonol dyes being preferred.

By way of example, the quantity of dye employed in the recording layer falls within a range of 1 to 100 weight percent, preferably 50 to 100 weight percent, and more preferably, a range of 75 to 100 weight percent of the total weight of the recording layer. When a compound denoted by general formula (I) is employed in combination with some other dye as the dye in the recording layer, the ratio of the compound denoted by general formula (I) to the total quantity of dye is preferably equal to or greater than 1 weight percent, more preferably 10 to 100 weight percent, and further preferably, 50 to 100 weight percent.

Various antifading agents may be incorporated into the recording layer to enhance the resistance to light of the recording layer. Examples of antifading agents are organic oxides and singlet oxygen quenchers. The compounds described in Japanese Unexamined Patent Publication (KOKAI) Heisei No. 10-151861, which is expressly incorporated herein by reference in its entirety, are desirable organic oxides for use as antifading agents. Singlet oxygen quenchers that are described in known publications such as patent specifications may be employed. Specific examples are described in Japanese Unexamined Patent Publication (KOKAI) Showa Nos. 58-175693, 59-81194, 60-18387, 60-19586, 60-19587, 60-35054, 60-36190, 60-36191, 60-44554, 60-44555, 60-44389, 60-44390, 60-54892, 60-47069, and 63-209995; Japanese Unexamined Patent Publication (KOKAI) Heisei No. 4-25492; Japanese Examined Patent Publication (KOKOKU) Heisei Nos. 1-38680 and 6-26028; German Patent No. 350399; and the Journal of the Japanese Chemical Society, October Issue, 1992, p. 1141, which are expressly incorporated herein by reference in their entirety. The compound denoted by general gormula (A) below is an example of a desirable singlet oxygen quencher.

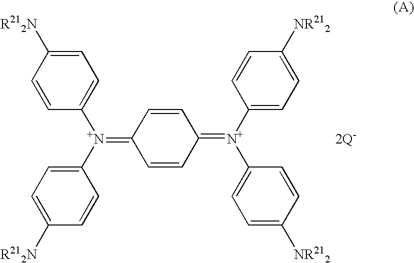

In general formula (A), R²¹ denotes an optionally substituted alkyl group and Q⁻ denotes an anion.

In general formula (A), R²¹ preferably denotes an optionally substituted alkyl group having 1 to 8 carbon atoms, more preferably an unsubstituted alkyl group having 1 to 6 carbon atoms. Examples of substituents on the alkyl group are: halogen atoms (such as F and Cl), alkoxy groups (such as methoxy groups and ethoxy groups), alkylthio groups (such as methylthio groups and ethylthio groups), acyl groups (such as acetyl groups and propionyl groups), acyloxy groups (such as acetoxy groups and propionyloxy groups), hydroxy groups, alkoxycarbonyl groups (such as methoxycarbonyl groups and ethoxycarbonyl groups), alkenyl groups (such as vinyl groups), and aryl groups (such as phenyl groups and naphthyl groups). Of these, halogen atoms, alkoxy groups, alkylthio groups, and alkoxycarbonyl groups are preferable. Preferable examples of the anion denoted by Q⁻ are: ClO₄⁻, AsF₆⁻, BF₄⁻, and SbF₆⁻.

Examples of the compound denoted by general formula (A) (Compound Nos. A-1 to A-8) are given in Table 2.

TABLE 2

| Compound No. | R²¹ | Q⁻ |
|---|---|---|
| A-1 | CH₃ | ClO⁴⁻ |
| A-2 | C₂H₅ | ClO⁴⁻ |
| A-3 | n-C₃H₇ | ClO⁴⁻ |
| A-4 | n-C₄H₉ | ClO⁴⁻ |
| A-5 | n-C₅H₁₁ | ClO⁴⁻ |
| A-6 | n-C₄H₉ | SbF⁶⁻ |
| A-7 | n-C₄H₉ | BF⁴⁻ |
| A-8 | n-C₄H₉ | AsF⁶⁻ |

The quantity of the above-described antifading agent, such as a singlet oxygen quencher, normally falls within a range of 0.1 to 50 weight percent, preferably a range of 0.5 to 45 weight percent, more preferably a range of 3 to 40 weight percent, and further preferably, a range of 5 to 25 weight percent of the quantity of dye.

Information can be recorded in the recording layer comprising the compound denoted by general formula (I) by irradiating the optical information recording medium of the present invention with a laser beam. Information can be recorded on the optical information recording medium by changing the optical characteristics of portions of the recording layer that are irradiated by the laser beam. The change in optical characteristics is thought to be the result of physical or chemical changes (such as the generation of pits) produced by increasing the temperature locally in portions of the recording layer by causing such portions to absorb light by irradiation with a laser beam. Information that has been recorded in the recording layer can be read (reproduced), for example, by scanning a laser beam of the same wavelength as the laser beam employed in recording and detecting the difference in an optical characteristic such as reflectance between portions in which the optical characteristics of the recording layer have been changed (recorded portions) and portions in which they have not changed (unrecorded portions). As set forth above, in the present invention, information is preferably recorded by thermally decomposing the substituent denoted by general formula (II) or (XIII) in the above-described compound by irradiation of a laser beam, thereby forming voids in pits by means of the gas thus generated. More preferably, the dye residue generated by general formula (III) generates heat by absorbing the laser beam, and the heat thus generated decomposes the substituent denoted by general formula (II) or (XIII), producing a gas. It is thought that this gas then forms voids in the recording layer, resulting in a large difference in refractive index between portions in which voids have been formed by irradiation by the laser beam and portions that have not been irradiated by the laser beam to enhance recording characteristics.

The optical information recording medium of the present invention comprises at least a recording layer comprising the compound denoted by general formula (I) on a support. In addition to the recording layer, it may comprise a light reflective layer, a protective layer, and the like.

Any of various materials employed as support materials in conventional optical information recording media may be employed as the support in the present invention.

Specific examples are: glass, acrylic resins such as polycarbonate and polymethyl methacrylate, vinyl chloride resins such as polyvinyl chloride and vinyl chloride copolymers, epoxy resins, amorphous polyolefin, polyester, and metals such as aluminum. These materials may be employed in combination as desired.

Among these materials, from the perspective of resistance to humidity, dimensional stability, and low cost, the use of amorphous polyolefin, polycarbonate, and other thermoplastic resins is preferable, and the use of polycarbonate is further preferable. When employing these resins, the support can be manufactured by injection molding.

The support thickness generally falls within a range of 0.7 to 2 mm, preferably a range of 0.9 to 1.6 mm, and more preferably, 1.0 to 1.3 mm.

An undercoating layer can be formed to enhance flatness and increase adhesion on the support surface on the side on which the light reflective layer, described further below, is positioned.

Tracking guide grooves or irregularities denoting information such as address signals (pregrooves) are normally formed on the surface of the support on which the recording layer is formed. In the optical information recording medium of the present invention, it is preferable to employ a support on which these are formed at a track pitch that is narrower than that of a CD-R or DVD-R so as to permit high-density recording. Details relating to the desirable range of the track pitch are given below.

Embodiments (1) and (2) below are examples of preferable embodiments of the optical information recording medium of the present invention.

Embodiment (1): An optical information recording medium comprising a dye-containing recordable recording layer and a cover layer 0.01 to 0.5 mm in thickness in this order on a support 0.7 to 2 mm in thickness.

Embodiment (2): An optical information recording medium comprising a dye-containing recordable recording layer and a protective support 0.1 to 1.0 mm in thickness in this order on a support 0.1 to 1.0 mm in thickness.

In embodiment (1), it is preferable for the track pitch of the pregrooves formed on the support to be 50 to 500 nm, the groove width to be 25 to 250 mm, and the groove depth to be 5 to 150 nm. In embodiment (2), it is preferable for the track pitch of the pregrooves formed on the substrate to be 200 to 600 nm, the groove width to be 50 to 300 nm, the groove depth to be 30 to 150 nm, and the wobble amplitude to be 5 to 50 nm.

### Optical Information Recording Medium of Embodiment (1)

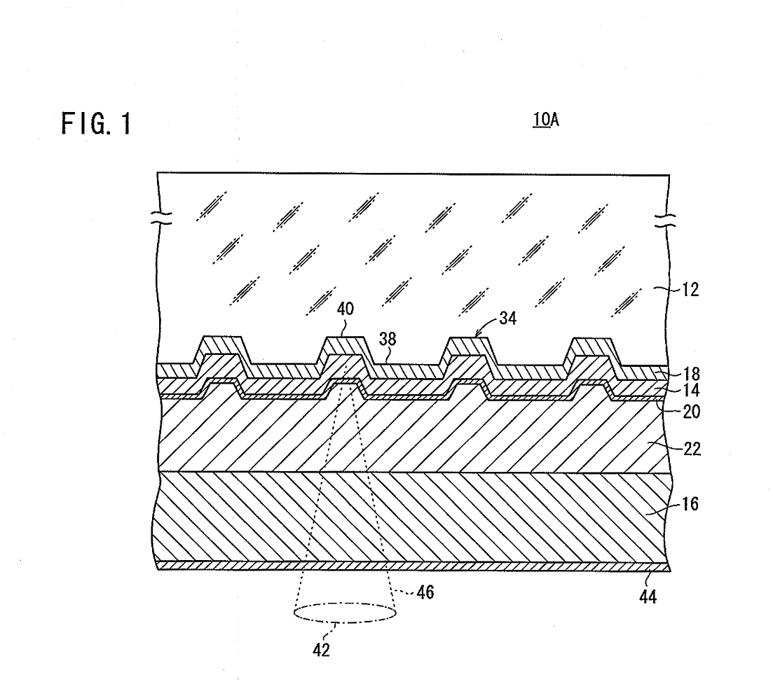

The optical information recording medium of embodiment (1) comprises at least a support, a recordable recording layer, and a cover layer. FIG. 1 shows a specific example of the optical information recording medium of embodiment (1). First optical information recording medium 10A shown in FIG. 1 is sequentially comprised of first light reflective layer 18, first recordable recording layer 14, barrier layer 20, first intermediate layer (bonding or adhesive layer) 22, and cover layer 16 on first support 12.

The materials constituting these components will be sequentially described below.

### Support

Pregrooves (guide grooves) having a shape such that the track pitch, groove width (half width), groove depth, and wobble amplitude are all within the ranges set forth below are formed on the support of embodiment (1). The pregrooves are provided to achieve a higher recording density than in a CD-R or DVD-R. For example, they are suited to when the optical information recording medium of the present invention is employed with a blue-violet laser.

The track pitch of the pregrooves falls within a range of 50 to 500 nm, the upper limit preferably being equal to or less than 420 nm, more preferably equal to or less than 370 nm, and still more preferably, equal to or less than 330 nm. The lower limit is preferably equal to or greater than 100 nm, more preferably equal to or greater than 200 nm, and still more preferably, equal to or greater than 260 nm. When the track pitch is equal to or greater than 50 nm, not only is it possible to correctly form the pregrooves, but the generation of crosstalk can be avoided. At equal to or less than 500 nm, high-density recording is possible.

The groove width (half width) of the pregrooves falls within a range of 25 to 250 nm, the upper limit preferably being equal to or less than 240 nm, more preferably equal to or less than 230 nm, and still more preferably, equal to or less than 220 nm. The upper limit is preferably equal to or greater than 50 nm, more preferably equal to or greater than 80 nm, and still more preferably, equal to or greater than 100 nm. When the pregroove width is equal to or greater than 25 nm, the grooves can be adequately transferred during forming and an increase in the error rate during recording can be inhibited. At equal to or less than 250 nm, the grooves can still be adequately transferred during forming, while the generation of crosstalk due to the widening of the pits formed during recording can be avoided.

The groove depth of the pregrooves falls within a range of 5 to 150 nm, the upper limit preferably being equal to or less than 85 nm, more preferably equal to or less than 80 nm, and still more preferably, equal to or less than 75 nm. The lower limit is preferably equal to or greater than 10 nm, more preferably equal to or greater than 20 nm, and still more preferably, equal to or greater than 28 nm. When the groove depth of the pregrooves is equal to or greater than 5 nm, an adequate degree of modulation can be achieved in recording, and at equal to or less than 150 nm, high reflectance can be achieved.

The upper limit of the groove tilt angle of the pregrooves is preferably equal to or less than 80°, more preferably equal to or less than 75°, further preferably equal to or less than 70°, and still more preferably, equal to or less than 65°. The lower limit is preferably equal to or greater than 20°, more preferably equal to or greater than 30°, and still more preferably, equal to or greater than 40°.

When the groove tilt angle of the pregrooves is equal to or greater than 20°, an adequate tracking error signal amplitude can be achieved, and at equal to or less than 80°, shaping properties are good.

### Recordable Recording Layer

The recordable recording layer of embodiment (1) can be formed as follows. A dye is dissolved in a suitable solvent with or without a binder or the like to prepare a coating liquid. Next, the coating liquid is coated on the support, or over a light reflective layer, described further below, to form a coating. The coating is then dried to form the recordable recording layer of embodiment (1). The recordable recording layer may be a single layer or multiple layers. When a multilayered structure is employed, the step of applying the coating liquid is conducted multiple times.

The concentration of the dye in the coating liquid normally falls within a range of 0.01 to 15 weight percent, preferably falls within a range of 0.1 to 10 weight percent, more preferably falls within a range of 0.5 to 5 weight percent, and still more preferably, falls within a range of 0.5 to 3 weight percent.

Examples of the solvent employed in preparing the coating liquid are: esters such as butyl acetate, ethyl lactate, and Cellosolve acetate; ketones such as methyl ethyl ketone, cyclohexanone, and methyl isobutyl ketone; chlorinated hydrocarbons such as dichloromethane, 1,2-dichloroethane, and chloroform; amides such as dimethylformamide; hydrocarbons such as methylcyclohexane, ethers such as tetrahydrofuran, ethyl ether, and dioxane; alcohols such as ethanol, n-propanol, isopropanol, and n-butanol diacetone alcohol; fluorine solvents such as 2,2,3,3-tetrafluoro-1-propanol; and glycol ethers such as ethylene glycol monomethylether, ethylene glycol monoethylether, and propylene glycol monomethylether.

The solvents may be employed singly or in combinations of two or more in consideration of the solubility of the dyes employed. Binders, oxidation inhibitors, UV absorbing agents, plasticizers, lubricants, and various other additives may be added to the coating liquid as needed.

Examples of coating methods are spraying, spincoating, dipping, roll coating, blade coating, doctor roll coating, and screen printing.

During coating, the temperature of the coating liquid preferably falls within a range of 23 to 50° C., more preferably within a range of 24 to 40° C., and further preferably, within a range of 23 to 38° C.

The thickness of the recordable recording layer is preferably equal to or less than 300 nm on lands (protrusions on the support), more preferably equal to or less than 250 nm, further preferably equal to or less than 200 nm, and still more preferably, equal to or less than 180 nm. The lower limit is preferably equal to or greater than 1 nm, more preferably equal to or greater than 3 nm, and still more preferably, equal to or greater than 5 nm.

The thickness of the recordable recording layer is preferably equal to or less than 400 nm on grooves (indentations in the support), more preferably equal to or less than 300 nm, and still more preferably, equal to or less than 250 nm. The lower limit is preferably equal to or greater than 10 nm, more preferably equal to or greater than 15 nm, and still more preferably, equal to or greater than 20 nm.

The ratio of the thickness of the recordable recording layer on lands to the thickness of the recordable recording layer on grooves (thickness on lands/thickness on grooves) is preferably equal to or greater than 0.1, more preferably equal to or greater than 0.13, further preferably equal to or greater than 0.15, and still more preferably, equal to or greater than 0.17. The upper limit is preferably equal to or less than 1, more preferably equal to or less than 0.9, further preferably equal to or less than 0.85, and still more preferably, equal to or less than 0.8.

To further enhance the resistance to light of the recordable recording layer, various antifading agents can be incorporated into the recordable recording layer. Singlet oxygen quenchers are normally employed as antifading agents. The singlet oxygen quenchers are as set forth above.

### Cover Layer

The cover layer in embodiment (1) is normally adhered through a bonding agent or adhesive onto the above-described recordable recording layer or onto a barrier layer such as that shown in FIG. 1.

The cover layer is not specifically limited, other than that it be a film of transparent material. An acrylic resin such as a polycarbonate or polymethyl methacrylate; a vinyl chloride resin such as polyvinyl chloride or a vinyl chloride copolymer; an epoxy resin; amorphous polyolefin; polyester; or cellulose triacetate is preferably employed. Of these, the use of polycarbonate or cellulose triacetate is more preferable.

The term “transparent” means having a transmittance of equal to or greater than 80 percent for the beam used in recording and reproducing.

The cover layer may further contain various additives so long as they do not compromise the effect of the present invention. For example, UV-absorbing agents may be incorporated to cut light with the wavelength of equal to or shorter than 400 nm and/or dyes may be incorporated to cut light with the wavelength of equal to or longer than 500 nm.

As for the physical surface properties of the cover layer, both the two-dimensional roughness parameter and three-dimensional roughness parameter are preferably equal to or less than 5 nm.

From the perspective of the degree of convergence of the beam employed in recording and reproducing, the birefringence of the cover layer is preferably equal to or lower 10 nm.

The thickness of the cover layer can be suitably determined based on the NA or wavelength of the laser beam irradiated in recording and reproducing. In the present invention, the thickness preferably falls within a range of 0.01 to 0.5 mm, more preferably a range of 0.05 to 0.12 mm.

The total thickness of the cover layer and bonding or adhesive layer is preferably 0.09 to 0.11 mm, more preferably 0.095 to 0.105 mm.

A protective layer (hard coating layer 44 in the embodiment shown in FIG. 1) may be provided on the incident light surface of the cover layer during manufacturing of the optical information recording medium to prevent scratching of the incident light surface.

An intermediate layer in the form of an adhesive layer can be provided between the cover layer and the recordable recording layer or barrier layer for adhesion.

Examples of the adhesive employed in the adhesive layer are acrylic, rubber, and silicone adhesives. From the perspectives of transparency and durability, acrylic adhesives are preferable. Preferable acrylic adhesive is an acrylic adhesive comprising a main component in the form of 2-ethylhexyl acrylate, n-butyl acrylate, or the like copolymerized with a short-chain alkyl acrylate or methacrylate, such as methyl acrylate, ethyl acrylate, or methyl methacrylate to increase the cohesive force, and the component capable of becoming a crosslinking point with a crosslinking agent, such as acrylic acid, methacrylic acid, an acrylamide derivative, maleic acid, hydroxylethyl acrylate, or glycidyl acrylate. The type and blending ratio of the main component, short-chain component, and component for the addition of a crosslinking point can be suitably adjusted to vary the glass transition temperature (Tg) and crosslinking density.

Isocyanates are examples of crosslinking agents that can be combined with the adhesive. Examples of isocyanate crosslinking agents that are suitable for use are: isocyanates such as tolylene diisocyanate, 4,4′-diphenylemthane diisocyanate, hexamethylene diisocyanate, xylylene diisocyanate, naphthylene-1,5-diisocyanate, o-toluidine isocyanate, isophorone diisocyanate, and triphenylmethane triisocyanate; products of these isocyanates and polyalcohols; and polyisocyanates produced by condensation of isocyanates. These isocyanates are commercially available under the trade names Coronate L, Coronate HL, Coronate 2030, Coronate 2031, Millionate MR, and Millionate HTL made by Nippon Polyurethane Industry Co., Ltd.; Takenate D-102, Takenate D-110N, Takenate D-200, and Takenate D-202 made by Takeda Pharmaceutical Co., Ltd.; Desmodur L, Desmodur IL, Desmodur N, and Desmodur HL made by Sumitomo Bayer Urethane Co., Ltd.

The method of forming the adhesive layer is not specifically limited. It is possible to uniformly coat a prescribed quantity of adhesive to the surface of the barrier layer or recordable recording layer (the surface being adhered), place the cover layer thereover, and cure the adhesive. It is also possible to uniformly coat a prescribed quantity of the adhesive to one surface of the cover layer to form an adhesive coating in advance, adhere the coating to the surface being adhered, and cure the adhesive coating.

It is also possible to employ a commercial adhesive film on which an adhesive layer has been provided in advance as a cover layer.

The thickness of the adhesive layer preferably falls within a range of 0.1 to 100 micrometers, more preferably within a range of 0.5 to 50 micrometers, and further preferably, within a range of 10 to 30 micrometers.

The cover layer may be formed by spin coating UV-curing resin.

When forming voids in the recording layer by irradiation of a laser beam as set forth above, since the formation of voids by irradiation of a laser beam is normally accompanied by distortion of the recording layer, and since impeding this distortion of the recording layer precludes good void formation, there is a risk of diminished recording characteristics. In an optical information recording medium comprising on a support a light reflective layer, a recording layer, a barrier layer, an adhesive layer, and a cover layer in this order, the support and the light reflective layer normally have greater rigidity than the adhesive layer and barrier layer. Thus, the recording layer pushes up the barrier layer during the formation of voids. When the layers positioned between the barrier layer and the cover layer are suitably flexible, a concave distortion can be produced in these layers. When the layers positioned between the barrier layer and cover layer can deform readily, it is possible to form good pits without impeding formation of voids in the recording layer. For good void formation, it is preferable for the adhesive layer to be suitably flexible.

### Other Layers

The optical information recording medium of embodiment (1) may optionally comprise other layers in addition to the above-described essential layers so long as the effect of the present invention is not compromised. Examples of such optional layers are a label layer having a desired image that is formed on the back of the support (the reverse unformed side from the side on which the recordable recording layer is formed), a light reflective layer positioned between the support and the recordable recording layer (described in detail further below), a barrier layer positioned between the recordable recording layer and the cover layer (described in detail further below), and a boundary layer positioned between the above light reflective layer and the recordable recording layer. The “label layer” may be formed from UV-curing resin, thermosetting resin, or heat-drying resin.

Each of the above-described essential layers and optional layers may have a single-layer or multilayer structure.

To increase reflectance for the laser beam and impart functions that enhance recording and reproducing characteristics to the optical information recording medium of embodiment (1), a light reflective layer is preferably formed between the support and the recordable recording layer.

The light reflective layer can be formed on the support by vacuum vapor deposition, sputtering, or ion plating of a light reflective substance with high reflectance for the laser beam.

The thickness of the light reflective layer generally falls within a range of 10 to 300 nm, preferably a range of 20 to 200 nm.

The above reflectance is preferably equal to or greater than 70 percent.

Examples of light reflective substances of high reflectance are: metals and semimetals such as Mg, Se, Y, Ti, Zr, Hf, V, Nb, Ta, Cr, Mo, W, Mn, Re, Fe, Co, Ni, Ru, Rh, Pd, Ir, Pt, Cu, Ag, Au, Zn, Cd, Al, Ga, In, Si, Ge, Te, Pb, Po, Sn, and Bi; and stainless steel. These light reflective substances may be employed singly, in combinations of two or more, or as alloys. Of these, the preferable substances are: Cr, Ni, Pt, Cu, Ag, Au, Al, and stainless steel; the more preferable substances are: Au, Ag, Al, and their alloys; and the substances of greatest preference are: Au, Ag, and their alloys.

### Barrier Layer

In the optical information recording medium of embodiment (1), as shown in FIG. 1, it is preferable to form a barrier layer between the recordable recording layer and the cover layer.

The barrier layer can be provided to enhance the storage properties of the recordable recording layer, enhance adhesion between the recordable recording layer and cover layer, adjust the reflectance, adjust thermal conductivity, and the like.

The material employed in the barrier layer is a material that passes the beam employed in recording and reproducing; it is not specifically limited beyond being able to perform this function. For example, it is generally desirable to employ a material with low permeability to gas and moisture, a material that does not corrode upon contact with a reflective layer material such as an Ag alloy; and a material that does not corrode in a hot, humid environment. A material that is also a dielectric is preferred.

Specifically, materials in the form of nitrides, oxides, carbides, and sulfides of Zn, Si, Ti, Te, Sn, Mo, Ge, and the like are preferable. MoO₂, GeO₂, TeO, SiO₂, TiO₂, ZuO, SnO₂, ZnO—Ga₂O₃, Nb₂O₅, and Ta₂O₅ are preferable and SnO₂, ZnO—Ga₂O₃, SiO₂, Nb₂O₅, and Ta₂O₅ are more preferable.

The barrier layer can be formed by vacuum film-forming methods such as vacuum vapor deposition, DC sputtering, RF sputtering, and ion plating. Of these, sputtering is preferred.

The thickness of the barrier layer preferably falls within a range of 1 to 200 nm, more preferably within a range of 2 to 100 nm, and further preferably, within a range of 3 to 50 nm.

### Optical Information Recording Medium of Embodiment (2)

The optical information recording medium of embodiment (2) comprises at least a support, a recordable recording layer, and a protective substrate, preferably in adhered form. Representative layer structures are given below:
(1) The first layer structure is a configuration in which a recordable recording layer, light reflective layer, and bonding layer are sequentially formed on a support, with a protective support being provided over the adhesive layer.
(2) The second layer structure is a configuration in which a recordable recording layer, light reflective layer, protective layer, and bonding layer are sequentially formed on a support, with a protective support being provided over the adhesive layer.
(3) The third layer structure is a configuration in which a recordable recording layer, light reflective layer, protective layer, bonding layer, and protective layer are sequentially formed on a support, with a protective support being provided over the protective layer.
(4) The fourth layer structure is a configuration in which a recordable recording layer, light reflective layer, protective layer, bonding layer, protective layer, and light reflective layer are sequentially formed on a support, with a protective support being provided over the light reflective layer.
(5) The fifth layer structure is a configuration in which a recordable recording layer, light reflective layer, bonding layer, and light reflective layer are sequentially formed on a substrate, with a protective support being provided over the reflective layer.

Layer structures (1) through (5) above are merely examples. The layer structure need not follow the order indicated above; some parts can be interchanged each other or can be omitted. The recordable recording layer may also be formed on the protective support side. In that case, an optical information recording medium capable of recording and reproducing from both sides is obtained. Further, each of the layers may be a single layer or comprised of multiple layers.

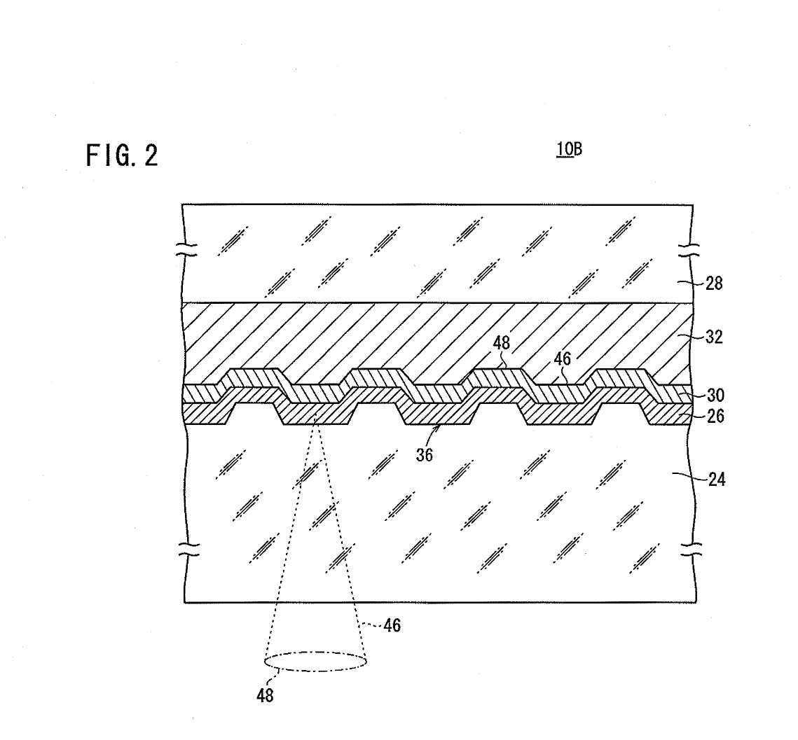

Among the above, the example of a configuration comprising, from the support side, a recordable recording layer, light reflective layer, bonding layer, and protective layer in this order on a support will be described in detail below as the optical information recording medium of embodiment (2). FIG. 2 shows a specific example of an optical information recording medium having the above configuration. As shown in FIG. 2, second optical information recording medium 10B comprises second recordable recording layer 26, second light reflective layer 30, second bonding layer 32, and protective substrate 28 in this order on second support 2.

### Support

Pregrooves (guide grooves) having a shape such that the track pitch, groove width (half width), groove depth, and wobble amplitude are all within the ranges set forth below are formed on the support of embodiment (2). The pregrooves are provided to achieve a higher recording density than in a CD-R or DVD-R. For example, they are suited to when the optical information recording medium of the present invention is employed with a blue-violet laser.

The track pitch of the pregrooves falls within a range of 200 to 600 nm, the upper limit preferably being equal to or less than 450 nm, more preferably equal to or less than 430 nm. The lower limit is preferably equal to or greater than 300 nm, more preferably equal to or greater than 330 nm, and still more preferably, equal to or greater than 370 nm. When the track pitch is equal to or greater than 200 nm, not only is it possible to correctly form the pregrooves, but the generation of crosstalk can be avoided. At equal to or less than 600 nm, high-density recording is possible.

The groove width (half width) of the pregrooves falls within a range of 50 to 300 nm, the upper limit preferably being equal to or less than 290 nm, more preferably equal to or less than 280 nm, and still more preferably, equal to or less than 250 nm. The upper limit is preferably equal to or greater than 100 nm, more preferably equal to or greater than 120 nm, and still more preferably, equal to or greater than 140 nm. When the groove width of the pregrooves is equal to or greater than 50 nm, the grooves can be adequately transferred during forming and an increase in the error rate during recording can be inhibited. At equal to or less than 300 nm, the generation of crosstalk due to the widening of the pits formed during recording can be avoided and a suitable degree of modulation can be achieved.

The groove depth of the pregrooves falls within a range of 30 to 150 nm, the upper limit preferably being equal to or less than 140 nm, more preferably equal to or less than 130 nm, and still more preferably, equal to or less than 120 nm. The lower limit is preferably equal to or greater than 40 nm, more preferably equal to or greater than 50 nm, and still more preferably, equal to or greater than 60 nm. When the groove depth of the pregrooves is equal to or greater than 30 nm, an adequate degree of modulation can be achieved in recording, and when equal to or less than 150 nms, high reflectance can be achieved.

The thickness of the support generally falls within a range of 0.1 to 1.0 mm, preferably a range of 0.2 to 0.8 mm, and more preferably, a range of 0.3 to 0.7 mm.

To improve flatness and increase adhesive strength, an undercoating layer can be formed on the surface of the support on the side on which the recordable recording layer, described further below, is formed.

Examples of materials employed in the undercoating layer are: polymeric substances such as polymethyl methacrylate, acrylic acid and methacrylic acid copolymers, styrene and maleic anhydride copolymers, polyvinylalcohol, N-methylolacrylamide, styrene and vinyltoluene copolymers, chlorosulfonated polyethylene, nitrocellulose, polyvinyl chloride, chlorinated polyolefin, polyester, polyimide, vinyl acetate and vinyl chloride copolymers, ethylene and vinyl acetate copolymers, polyethylene, polypropylene, and polycarbonate; and surface modifying agents such as silane coupling agents.

The undercoating layer can be formed by dissolving or dispersing the above material in a suitable solvent to prepare a coating liquid, and coating the coating liquid to the surface of the support by a coating method such as spin coating, dip coating, or extrusion coating.

The thickness of the undercoating layer normally falls within a range of 0.005 to 20 micrometers, preferably within a range of 0.01 to 10 micrometers.

### Recordable Recording Layer

Details of the recordable recording layer in embodiment (2) are identical to those of the recordable recording layer in embodiment (1).

### Light Reflective Layer

A light reflective layer can be formed on the recordable recording layer in embodiment (2) to increase reflectance for the laser beam and impart functions that improve recording and reproducing characteristics. Details of the light reflective layer in embodiment (2) are identical to those of the light reflective layer in embodiment (1).

### Bonding Layer

A bonding layer can be provided between the light reflective layer and the protective layer in embodiment (2) to increase adhesion between above-described the light reflective layer and the protective support, described further below.

Photosetting resins are preferable as the material included in the bonding layer, with a photosetting resin having a low curing shrinkage rate being more preferable to prevent warping of the disk. Examples of such photosetting resins are UV-curable resins (UV-curable bonding agents) such as SD-640 and SD-661 made by Dainippon Ink and Chemicals, Inc.

The thickness of the bonding layer preferably falls within a range of 1 to 1,000 micrometers to impart elasticity.

### Protective Support

The protective support (dummy support) in embodiment (2) may be of the same material and shape as the above-described support. The thickness of the protective support normally falls within a range of 0.1 to 1.0 mm, preferably falls within a range of 0.2 to 0.8 mm, and more preferably falls within a range of 0.3 to 0.7 mm. When manufacturing a recording medium having multiple recording layers, it is also possible for pregrooves and layers such as recordable recording layers and reflective layers to be provided on the protective support side. This method is sometimes referred to as the inverse stacking method. The recording and reproducing wavelength for the recording layers formed on the protective support side may be identical to or different from that of the recording layer provided on the support that is not a protective support. Specifically, the track pitch, groove shape, and various layer materials such as the recordable recording layer material, reflective layer material, and undercoating layer material may be identical or different among multiple recording layers.

### Protective Layer

Depending on the layer structure of the optical information recording medium of embodiment (2), protective layers may be provided to physically or chemically protect light reflective layers, recordable recording layers, and the like.

Examples of the material employed in the protective layers are: inorganic substances such as ZnS, ZnS—SiO₂, SiO, SiO₂, MgF₂, SnO₂, and Si₃N₄; and organic substances such as thermoplastic resins, thermosetting resins, and UV-curable resins.

The protective layer can be formed, for example, by adhering a film obtained by plastic extrusion processing through an adhesive to the light reflective layer. It may also be provided by a method such as vacuum vapor deposition, sputtering, or coating.

When a thermoplastic resin or thermosetting resin is employed as the protective layer, the protective layer may be formed by dissolving the resin in a suitable solvent to prepare a coating liquid, and then coating and drying the coating liquid. When forming a protective layer with a UV-curable resin, the UV-curable resin may be employed as is or dissolved in a suitable solvent to prepare a coating liquid, which is then coated and cured by irradiation with UV light. Various additives such as antistatic agents, oxidation inhibitors, and UV-absorbing agents may be added to the coating liquid depending on the objective.

The thickness of the protective layer normally falls within a range of 0.1 micrometer to 1 mm.

### Other Layers

In addition to the above-described layers, other optional layers may be present in the optical information recording medium of embodiment (2) to the extent that the effect of the present invention is not compromised. Details of these other optional layers are identical to those of the other optional layers of embodiment (1).

### Method of Recording Information

The present invention further relates to a method of recording information on an optical information recording medium comprising a recording layer on a support. In the method of recording information of the present invention, information is recorded on a recording layer comprising the compound denoted by general formula (I) by irradiation of a laser beam onto the optical information recording medium of the present invention.

By way of example, information is recorded on the above-described preferred optical information recording medium of embodiment (1) or (2) in the following manner.

First, while rotating an optical information recording medium at a certain linear speed (such as 0.5 to 10 m/s) or a certain angular speed, a laser beam for recording, such as a semiconductor laser beam, is directed from the support side or protective layer side. Irradiation by this laser beam changes the optical properties of the portions that are irradiated, thereby recording information. In the embodiment shown in FIG. 1, recording laser beam 46 such as a semiconductor laser beam is directed from cover layer 16 side through first object lens 42 (having a numerical aperture NA of 0.85, for example). Irradiation by laser beam 46 causes recordable recording layer 14 to absorb laser beam 46, resulting in a local rise in temperature. This is thought to produce a physical or chemical change (such as generating pits), thereby altering the optical characteristics and recording information. Similarly, as shown in the embodiment of FIG. 2, recording laser beam 46 such as a semiconductor laser beam is directed through second object lens 48 of a numerical aperture NA of 0.65, for example, from second support 24 side. Irradiation by laser beam 46 causes second recordable recording layer 26 to absorb laser beam 46, resulting in a local rise in temperature. This is thought to produce a physical or chemical change (such as generating pits), thereby altering the optical characteristics and recording information.

In the present invention, information is preferably recorded by irradiation of a laser beam having a wavelength of equal to or shorter than 440 nm. A semiconductor laser beam having an oscillation wavelength falling within a range of equal to or shorter than 440 nm is suitable for use as a recording beam. A blue-violet semiconductor laser beam having an oscillation wavelength falling within a range of 390 to 440 nm (preferably 390 to 415 nm) and a blue-violet SHG laser beam having a core oscillation wavelength of 425 nm obtained by halving the wavelength of an infrared semiconductor laser beam having a core oscillation wavelength of 850 nm with an optical waveguide device are examples of preferable light sources. In particular, a blue-violet semiconductor laser beam having an oscillation wavelength of 390 to 415 nm is preferably employed from the perspective of recording density. The information that is thus recorded can be reproduced by directing the semiconductor laser beam from the support side or protective layer side while rotating the optical information recording medium at the same constant linear speed as above, and detecting the reflected beam.

The remaining details of the method of recording information of the present invention are as set forth above in the description of the optical information recording medium of the present invention.

### EXAMPLES

The present invention will be described in detail below based on examples. However, the present invention is not limited to the examples.

### Synthesis Example 1

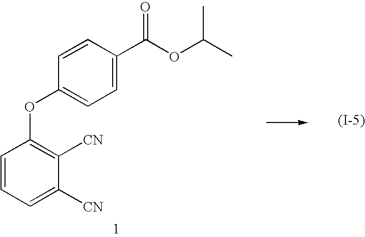

A 3.06 g quantity of Compound 1 was added to 3 mL of diethylene glycol and 6 mL of 1-methoxy-2-propanol, 0.453 g of copper (II) acetate and 1.35 g of ammonium benzoate were added, and the mixture was stirred for 4 hours at 140° C. The mixture was allowed to cool to room temperature, washed with acetonitrile, and filtered, yielding 2.52 g of compound (I-5). MS spectra confirmed that the target compound had been obtained.

### Synthesis Example 2

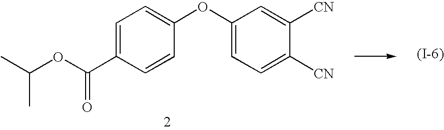

A 3.06 g quantity of Compound 2 was added to 3 mL of diethylene glycol and 6 mL of 1-methoxy-2-propanol, 0.453 g of copper (II) acetate and 1.35 g of ammonium benzoate were added, and the mixture was stirred for 4 hours at 140° C. The mixture was allowed to cool to room temperature, washed with acetonitrile, and then filtered, yielding 2.41 g of compound (I-6). MS spectra confirmed that the target compound had been obtained.

### Synthesis Example 3

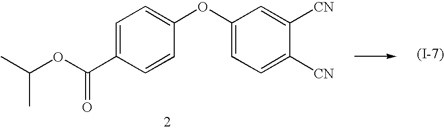

To 1.53 g of Compound 2 and 0.23 g of magnesium (II) bromide was added dropwise 1.3 mL of dimethylformamide. A 2.1 mL quantity of hexamethyldisilane was further added and the mixture was reacted for 7 hours at 100° C. with stirring. When the reaction had ended, the reaction product was allowed to cool and filtered with methanol, yielding 0.60 g of Compound (I-7). MS spectra confirmed that the target compound had been obtained.

### Synthesis Example 4

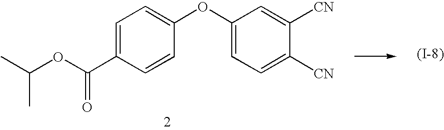

To 1.96 g of Compound 2 and 0.28 g of zinc (II) bromide was added dropwise 3.4 mL of dimethylformamide. A 2.1 mL quantity of hexamethyldisilane was further added and the mixture was reacted for 5 hours at 100° C. with stirring. When the reaction had ended, the reaction product was allowed to cool and filtered with methanol, yielding 1.66 g of Compound (I-8). MS spectra confirmed that the target compound had been obtained.

### Synthesis Example 5

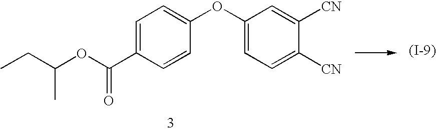

A 1.60 g quantity of Compound 3 was added to 1.5 mL of diethylene glycol and 3 mL of 1-methoxy-2-propanol. A 0.227 g quantity of copper (II) acetate and 0.695 g of ammonium benzoate were added and the mixture was stirred for 6 hours at 140° C. The reaction product was cooled to room temperature, washed with methanol, and filtered, yielding 0.4 g of Compound (I-9). MS spectra confirmed that the target compound had been obtained.

### Synthesis Example 6

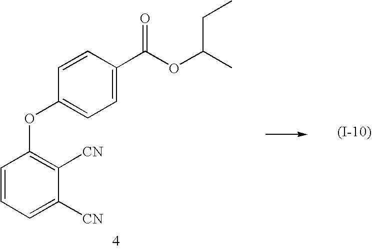

A 1.60 g quantity of Compound 4 was added to 1.5 mL of diethylene glycol and 3 mL of 1-methoxy-2-propanol. A 0.227 g quantity of copper (II) acetate and 0.695 g of ammonium benzoate were added and the mixture was stirred for 6 hours at 140° C. The reaction product was cooled to room temperature, washed with methanol, and filtered, yielding 1.0 g of Compound (I-10). MS spectra confirmed that the target compound had been obtained.

### Synthesis Example 7

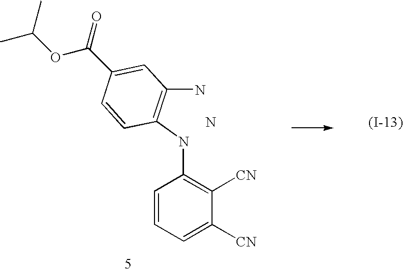

A 1.66 g quantity of Compound 5 was added to 3 mL of diethylene glycol and 6 mL of 1-methoxy-2-propanol. A 0.227 g quantity of copper (II) acetate and 0.675 g of ammonium benzoate were added and the mixture was stirred for 8 hours at 140° C. The reaction product was cooled to room temperature, washed with methanol, and filtered, yielding 1.45 g of Compound (I-13). MS spectra confirmed that the target compound had been obtained.

### Synthesis Example 8

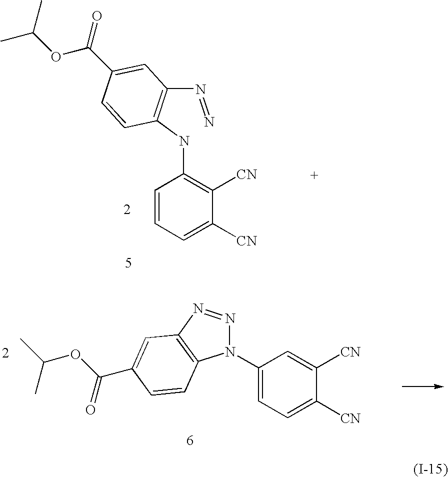

A 0.83 g quantity of Compound 5 and 0.83 g of Compound 6 were added to 3 mL of diethylene glycol and 6 mL of 1-methoxy-2-propanol. A 0.227 g quantity of copper (II) acetate and 0.675 g of ammonium benzoate were added and the mixture was stirred for 8 hours at 140° C. The reaction product was cooled to room temperature, washed with methanol, and filtered, yielding 1.27 g of Compound (I-15). MS spectra confirmed that the target compound had been obtained.

### Synthesis Example 9

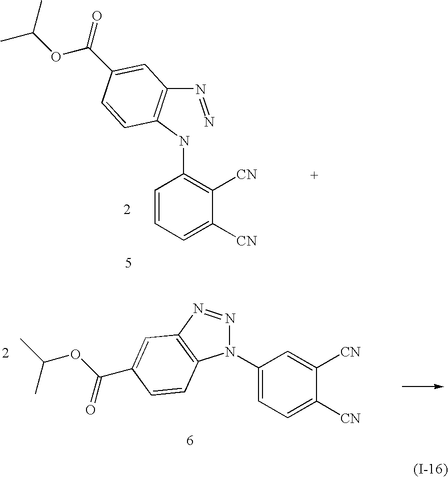

To 0.83 g of Compound 5, 0.83 g of Compound 6, and 0.23 g of magnesium (II) bromide was added dropwise 1.3 mL of dimethylformamide. A 2.1 mL quantity of hexanemethyldisilazane was further added and the mixture was reacted for 8 hours at 100° C. with stirring. When the reaction had ended, the reaction product was allowed to cool and filtered with methanol, yielding 1.50 g of compound (I-16). MS spectra confirmed that the target compound had been obtained.

### Synthesis Example 10

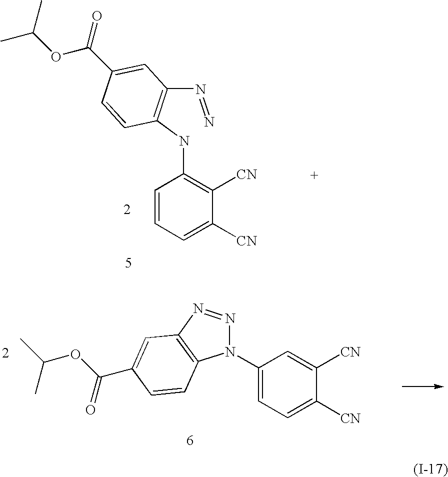

To 0.43 g of Compound 5, 0.43 g of Compound 6, and 0.28 g of zinc (II) bromide was added dropwise 1.3 mL of dimethylformamide. A 2.1 mL quantity of hexanemethyldisilazane was further added and the mixture was reacted for 8 hours at 100° C. with stirring. When the reaction had ended, the reaction product was allowed to cool and filtered with methanol, yielding 0.68 g of compound (I-17). MS spectra confirmed that the target compound had been obtained.

### Reference Synthesis Examples

Comparative Compounds II-1 and II-2 indicated in Table 3 below were synthesized by the following methods.

TABLE 3

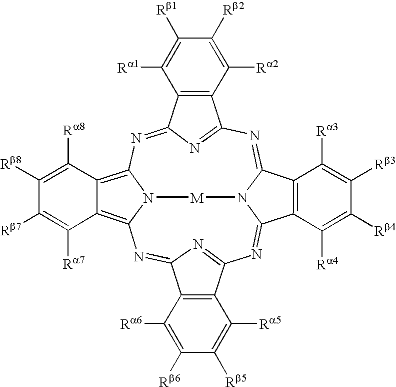

| No. | Position and type of substituent | M |
|---|---|---|
| (II-1) | R^{β1}/R^{β2}, R^{β3}/R^{β4}, R^{β5}/R^{β6}, R^{β7}/R^{β8} | Cu |
| | 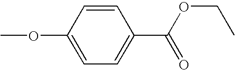 | |
| (II-2) | R^{α1}/R^{α2}, R^{α3}/R^{α4}, R^{α5}/R^{α6}, R^{α7}/R^{α8} | Cu |
| | 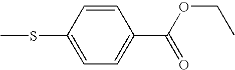 | |

### 1. Synthesis of Comparative Compound II-1

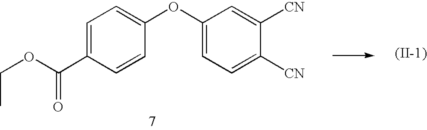

A 2.92 g quantity of Compound 7 was added to 3 mL of diethylene glycol and 6 mL of 1-methoxy-2-propanol. A 0.45 g quantity of copper (II) acetate and 1.39 g of ammonium benzoate were added and the mixture was stirred for 4 hours at 100° C. The reaction product was allowed to cool to room temperature, washed with acetonitrile, and filtered, yielding 2.3 g of Compound (II-1). MS spectra confirmed that the target compound had been obtained.

### 2. Synthesis of Comparative Compound II-2

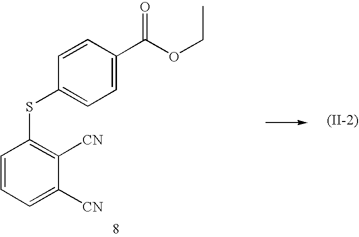

A 1.00 g quantity of Compound 8 was added to 1 mL of diethylene glycol and 2 mL of 1-methoxy-2-propanol. A 0.15 g quantity of copper (II) acetate and 0.45 g of ammonium benzoate were added and the mixture was stirred for 6 hours at 140° C. The reaction product was cooled to room temperature, washed with acetonitrile, and filtered, yielding 0.6 g of Compound (II-2). MS spectra confirmed that the target compound had been obtained.

### Examples 1 to 8

### Preparation of Optical Information Recording Medium

(Preparation of Support)

An injection-molded substrate comprised of polycarbonate resin, having spiral pregrooves 1.1 mm in thickness, 120 mm in outer diameter and 15 mm in inner diameter (track pitch: 320 nm; in-groove width: 140 nm; groove depth: 40 nm; groove tilt angle: 65°; wobble amplitude: 20 nm) was prepared. Mastering of the stamper employed during injection-molding was conducted by electronic beam cutting.

(Formation of Light Reflective Layer)

Under an argon atmosphere, DC sputtering was used to form a light reflective layer of AgNdCu alloy (Ag: 98.1 at %, Nd: 0.7 at %, and Cu: 0.9 at %) in the form of a vacuum film layer 100 nm in thickness on the support with a cube made by Unaxis Corp. The film thickness was 100 nm. The film thickness on the light reflective layer was adjusted by adjusting the sputtering duration.

(Formation of Recordable Recording Layer)

A 2 g quantity of each of Example Compounds (I-5), (I-6), (I-9), (I-10), (I-13), (I-15), (I-16), and (I-17) was dissolved in 100 mL of 2,2,3,3-tetrafluoropropanol to prepare a dye-containing coating liquid. The dye-containing coating liquid that had been prepared was coated by spin coating on the light reflective layer under conditions of 50% RH and 23° C. while varying the rotational speed from 300 to 4,000 rpm. Subsequently, the product was stored for one hour at 50% RH and 23° C. to form a recordable recording layer. The thickness of the recordable recording layer was 40 nm on grooves and 15 nm on lands.

Following formation of the recordable recording layer, annealing was conducted in a clean oven. Annealing was conducted by supporting the support perpendicular to a stack pole and at some distance with a spacer for one hour at 80° C.

(Formation of Barrier Layer)

Subsequently, a barrier layer 5 nm in thickness comprised of Nb₂O5 was formed on the recordable recording layer by RF sputtering in an argon atmosphere using a cube made by Unaxis Corp.

(Adhesion of Cover Layer with Adhesive)

A film (80 micrometers, Teijin Pureace) of polycarbonate having an inner diameter of 15 mm and an outer diameter of 120 mm that had been coated on one side with an acrylic adhesive (Tg: −30° C.) was employed as the cover layer. Adjustments were made so that the total thickness of the adhesive layer and the polycarbonate film was 100 micrometers. That is, the thickness of the adhesive layer was 20 micrometers.

The cover layer was positioned on the barrier layer so that the barrier layer contacted the adhesive layer, after which the cover layer was pressed down with a member, causing it to adhere.

### Comparative Examples 1 to 4

With the exception that Comparative Compound (II-1) or (II-2) mentioned above, the following Comparative Compound (II-3) or (II-4) described in Example 1 of Japanese Unexamined Patent Publication (KOKAI) No. 2005-228402, which is expressly incorporated herein by reference in its entirety) was added to the recording layer instead of Example Compound, an optical information recording media of Comparative Examples 1 to 4 were prepared by the same method as in Example 1.

TABLE 4

| No. | Position and type of substituent | M |
|---|---|---|
| (II-3) | R^{α1}/R^{α2}, R^{α3}/R^{α4}, R^{α5}/R^{α6}, R^{α7}/R^{α8} | Cu |
| | 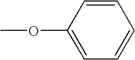 | |
| (II-4) | R^{α1}/R^{α2}, R^{α3}/R^{α4}, R^{α5}/R^{α6}, R^{α7}/R^{α8} | Cu |
| | —SO₂CH(CH₃)CH₂CH₃ | |

<Evaluation of the Optical Information Recording Media>

### Evaluation of C/N (Carrier/Noise Ratio)

A 0.16 micrometer signal (2T) was recorded on and reproduced from the prepared optical information recording media at a clock frequency of 66 MHz and a linear speed of 4.92 m/s with an apparatus for evaluating recorded and reproduced information (DDU1000 made by Pulsetech Corp.) equipped with a 403 nm laser and an NA 0.85 pickup, and the output was measured with a spectral analyzer (FSP-3 made by Rohde-Schwarz). Peak output observed in the vicinity of 16 MHz following recording was adopted as the carrier output, and the output at the same frequency before recording was adopted as the noise output. The output following recording minus the output prior to recording was taken as the C/N value. Recording was conducted on grooves. The recording power was 4.5 mW and the reproducing power was 0.3 mW. A C/N value of equal to or greater than 35 dB was considered to be a practical level. The results are shown in Table 5.

<Decomposition Temperature>

A TG-DTA device in the form of an EXSTAR 6000 made by Seiko Instruments, Inc. was employed to raise the temperature at a rate of 10° C./min over a range of 30 to 550° C. under an N₂ gas flow (flow rate 200 mL/min), and the thermal decomposition temperature was obtained as the temperature at the point where the weight reduction rate reached 10 percent for the example compounds and comparative compounds. The results are given in Table 5.

<Solubility in TFP>

The solubility of the example compounds and comparative compounds in 2,2,3,3-tetrafluoropropanol (TFP) was evaluated by the following method.

A 2 g quantity of the compound was added to 100 mL of TFP and dissolved to prepare a dye-containing coating liquid. Based on visual observation, a state of complete dissolution was evaluated as “soluble” and a state where insoluble matter was visible as “insoluble.” The results are given in Table 5.

TABLE 5

| | | Decomposition | Solubility | |
|---|---|---|---|---|
| | Dye | temperature | in TFP | C/N value |
| Ex. 1 | Ex. Compound (I-5) | 352° C. | Soluble | 37 dB |
| Ex. 2 | Ex. Compound (I-6) | 342° C. | Soluble | 38 dB |
| Ex. 3 | Ex. Compound (I-9) | 333° C. | Soluble | 39 dB |
| Ex. 4 | Ex. Compound (I-10) | 340° C. | Soluble | 38 dB |
| Ex. 5 | Ex. Compound (I-13) | 336° C. | Soluble | 41 dB |
| Ex. 6 | Ex. Compound (I-15) | 335° C. | Soluble | 40 dB |
| Ex. 7 | Ex. Compound (I-16) | 320° C. | Soluble | 45 dB |
| Ex. 8 | Ex. Compound (I-17) | 330° C. | Soluble | 45 dB |
| Comp. Ex. 1 | Compound (II-1) | 403° C. | Insoluble | Measurement was |
| | | | | not possible. |
| Comp. Ex. 2 | Compound (II-2) | 402° C. | Soluble | 29 dB |
| Comp. Ex. 3 | Compound (II-3) | Equal to or greater | Insoluble | Measurement was |
| | | than 500° C. | | not possible. |
| Comp. Ex. 4 | Compound (II-4) | 353 | Soluble | 40 dB |

Light-Toughness Evaluation Results

### <Evaluation of Resistance to Light of Dye Film>

A 2 g quantity of each compound employed in Example 1 to 8 and in Comparative Example 2 and 4 was added to 100 mL of 2,2,3,3-tetrafluoropropanol and dissolved to prepare a dye-containing coating liquid. A dye film was formed by spin coating the dye-containing liquid that had been prepared on a glass sheet 1.0 mm in thickness under conditions of 23° C. and 50 percent RH while varying the rotational speed from 500 to 1,000 rpm. Subsequently, the glass sheet on which the dye film had been formed was stored for 24 hours at 50 percent RH and 23° C. A merry-go-round type light resistance tester (made by Eagle Engineering, Inc., Cell Tester III, with WG320 filter made by Schott) was then used to conduct a light resistance test. The absorption spectra of the dye film immediately prior to the light resistance test and 48 hours after the light resistance test were measured with a UV-1600PC (made by Shimadzu Corp.). Dye films with a remaining rate of equal to or greater than 95 percent were determined to be suitable for practical use. The change in absorbance at the maximum absorption wavelength was read; the results are given in Table 6.

TABLE 6

| | Light-toughness |
|---|---|
| | Remaining rate 48 |
| No. | hours after (%) |
| Ex. 1 (Compound I-5) | >99 |
| Ex. 2 (Compound I-6) | >99 |
| Ex. 3 (Compound I-9) | >99 |
| Ex. 4 (Compound I-10) | >99 |
| Ex. 5 (Compound I-13) | >99 |
| Ex. 6 (Compound I-15) | >99 |
| Ex. 7 (Compound I-16) | >99 |
| Ex. 8 (Compound I-17) | >99 |
| Comp. Ex. 2 (Compound II-2) | >99 |
| Comp. Ex. 4 (Compound II-4) | 93 |

As shown in Table 5, the optical information recording media of Examples 1 to 8 exhibited good recording characteristics. As shown in Tables 5 and 6, the compound employed as the recording layer dye had good solubility and light-fastness.

By contrast, in the optical information recording media of Comparative Examples 1 and 3, as shown in Table 5, the low solubility of the recording layer dye precluded manufacturing of a recording medium, so no evaluation of recording on a recording medium was possible. As shown in Table 5, the optical information recording medium of Comparative Example 2 exhibited poor recording characteristics.

As shown in FIG. 5, the optical information recording medium of Comparative Example 4 had good recording properties, but as shown in FIG. 6, the light-toughness of the recording layer dye was poor.

The above results indicate that an optical recording medium with good light-toughness and good recording characteristics for a short-wavelength laser beam can be obtained according to the present invention.

The optical information recording medium of the present invention is suitable as an optical information recording medium for the recording of information by irradiation of a short-wavelength laser beam.

Although the present invention has been described in considerable detail with regard to certain versions thereof, other versions are possible, and alterations, permutations and equivalents of the version shown will become apparent to those skilled in the art upon a reading of the specification and study of the drawings. Also, the various features of the versions herein can be combined in various ways to provide additional versions of the present invention. Furthermore, certain terminology has been used for the purposes of descriptive clarity, and not to limit the present invention. Therefore, any appended claims should not be limited to the description of the preferred versions contained herein and should include all such alterations, permutations, and equivalents as fall within the true spirit and scope of the present invention.

Having now fully described this invention, it will be understood to those of ordinary skill in the art that the methods of the present invention can be carried out with a wide and equivalent range of conditions, formulations, and other parameters without departing from the scope of the invention or any embodiments thereof.

All patents and publications cited herein are hereby fully incorporated by reference in their entirety. The citation of any publication is for its disclosure prior to the filing date and should not be construed as an admission that such publication is prior art or that the present invention is not entitled to antedate such publication by virtue of prior invention.

Unless otherwise stated, a reference to a compound or component includes the compound or component by itself, as well as in combination with other compounds or components, such as mixtures of compounds.

As used herein, the singular forms “a,” “an,” and “the” include the plural reference unless the context clearly dictates otherwise.

Except where otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention. At the very least, and not to be considered as an attempt to limit the application of the doctrine of equivalents to the scope of the claims, each numerical parameter should be construed in light of the number of significant digits and ordinary rounding conventions.

Additionally, the recitation of numerical ranges within this specification is considered to be a disclosure of all numerical values and ranges within that range. For example, if a range is from about 1 to about 50, it is deemed to include, for example, 1, 7, 34, 46.1, 23.7, or any other value or range within the range.

What is claimed is:

1. An optical information recording medium comprising a recording layer comprising a dye on a support, wherein
said dye is a compound denoted by general formula (I). 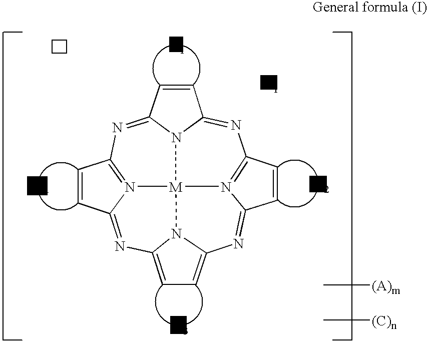
[In general formula (I), A denotes a hydrogen atom or a substituent, B₁, B₂, B₃, and B₄ each independently denote an atom group forming an aromatic ring with two terminal carbon atoms, M denotes two hydrogen atoms, a divalent to tetravalent metal atom, a metal oxide, a metal atom having a ligand, or a metal oxide having a ligand, C denotes (L-(D)₁) or E, D and E each independently denote a monovalent substituent denoted by general formula (II) or (XIII), L denotes a divalent linking group, l denotes an integer ranging from 1 to 10, m denotes an integer ranging from 0 to 15, n denotes an integer ranging from 1 to 16, wherein m+n=16, plural As may be identical or different from each other when m is an integer of equal to or greater than 2, and plural (L-(D)₁)s or Es may be identical or different from each other when n is an integer of equal to or greater than 2.] 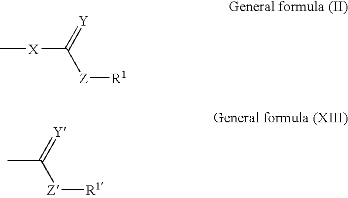
[In general formulas (II) and (XIII), R¹ and R^{1′each} independently denote a secondary alkyl group, X denotes a sulfur atom, an oxygen atom, NR², or CR³R⁴, Y and Y′ each independently denote an oxygen atom or a sulfur atom, Z and Z′ each independently denote NR², an oxygen atom, or a sulfur atom, and R², R³, and R⁴ each independently denote a hydrogen atom or a monovalent substituent.]

2. The optical information recording medium of claim 1, wherein both of Y and Z in general formula (II) are an oxygen atom and/or both of Y′ and Z′ in general formula (XIII) are an oxygen atom.

3. The optical information recording medium of claim 1, wherein the compound denoted by general formula (I) has a thermal decomposition temperature ranging from 300 to 400° C.

4. The optical information recording medium of claim 1, which comprises said recording layer, a barrier layer, an adhesive layer, and a cover layer in this order on the support.

5. A method of recording information on the recording layer comprised in the optical information recording medium of claim 1 by irradiation of a laser beam onto the optical information recording medium.

6. The method of recording information of claim 5, wherein the laser beam has a wavelength ranging from 390 to 440 nm.
